(19) United States
(12) Patent Application Publication
(10) Pub. No.: US 2012/0211821 A1
(43) Pub. Date: Aug. 23, 2012

(54) SEMICONDUCTOR MEMORY DEVICE, METHOD FOR MANUFACTURING SAME, AND METHOD FOR MANUFACTURING INTEGRATED CIRCUIT DEVICE

(75) Inventor: Takanori MATSUMOTO, Mie-ken (JP)

(73) Assignee: Kabushiki Kaisha Toshiba, Tokyo (JP)

(21) Appl. No.: 13/236,828

(22) Filed: Sep. 20, 2011

(30) Foreign Application Priority Data
Feb. 23, 2011 (JP) 2011-036796

(51) Int. Cl. H01L 21/28; H01L 27/088; H01L 21/336

(52) U.S. Cl. 257/324; 438/478; 438/702; 257/E21.21; 257/E21.423; 257/E27.06

(57) ABSTRACT

According to one embodiment, a method for manufacturing a semiconductor memory device includes forming a first stacked body on a substrate by alternately stacking a first film and a second film, forming a second stacked body on the first stacked body by alternately stacking a third film and a fourth film, making a through-hole to pierce the second stacked body and the first stacked body by performing etching, an etching rate of the third film being lower than an etching rate of the first film in the etching, forming a charge storage film on an inner surface of the through-hole, and forming a semiconductor member in the through-hole. The first film and the second film are formed of mutually different materials. The third film and the fourth film are formed of mutually different materials. And, the first film and the third film are formed of mutually different materials.

### CROSS-REFERENCE TO RELATED APPLICATIONS

This application is based upon and claims the benefit of priority from the prior Japanese Patent Application No. 2011-036796, filed on Feb. 23, 2011; the entire contents of which are incorporated herein by reference.

### FIELD

Embodiments described herein relate generally to a semiconductor memory device, a method for manufacturing the same and a method for manufacturing an integrated circuit device.

### BACKGROUND

Semiconductor memory devices including flash memory and the like conventionally have been constructed by two-dimensionally integrating memory cells on a surface of a silicon substrate. Although higher integration of the memory cells is necessary in such semiconductor memory devices to reduce the cost per bit and increase the storage capacity, increasing the integration in recent years has become difficult in regard to both cost and technology.

As technology to breakthrough the limitations of increasing the integration, there are methods that three-dimensionally integrate memory cells by stacking. However, in methods that simply stack and pattern one layer at a time, the number of processes undesirably increases as the number of stacks increases; and the costs undesirably increase. Therefore, technology has been proposed to form a stacked body on a silicon substrate by alternately stacking gate electrodes and insulating films; subsequently collectively patterning through-holes in the stacked body; depositing a blocking insulating film, a charge storage film, and a tunneling insulating film in this order on the side surface of the through-hole; and burying a silicon pillar in the interior of the through-hole.

In such a collectively patterned three-dimensionally stacked memory, a charge can be removed from and put into the charge storage film from the silicon pillar to store information by forming memory cell transistors at the intersections between the silicon pillar and each of the gate electrodes and by controlling the potentials of each of the gate electrodes and each of the silicon pillars. According to such technology, the through-holes can be made by collectively patterning the stacked body. Therefore, the number of lithography processes does not increase and cost increases can be suppressed even in the case where the number of stacks of the gate electrodes increases.

However, in such a collectively patterned three-dimensionally stacked memory, even higher integration and downscaling of the planar structure are necessary.

### BRIEF DESCRIPTION OF THE DRAWINGS

FIG. 1 and FIG. 2 are cross-sectional views of processes, illustrating a method for manufacturing a semiconductor memory device according to a first embodiment;

FIG. 3 is a cross-sectional view of a process, illustrating a method for manufacturing a semiconductor memory device according to a first comparative example;

FIG. 4 is a cross-sectional view of a process, illustrating a method for manufacturing a semiconductor memory device according to a second comparative example;

FIG. 5 is a cross-sectional view of a process, illustrating a method for manufacturing a semiconductor memory device according to a second embodiment;

FIGS. 6A to 6D schematically illustrate samples evaluated for a first test example;

FIG. 7 illustrates a displacement amount of a through-hole;

FIG. 8 is a graph illustrating a state of a meandering of the through-hole;

FIGS. 9A to 9F schematically illustrate samples evaluated for a second test example;

FIG. 10 is a graph illustrating an effect of a proportion of a thickness of a stacked body on a displacement amount of a through-hole;

FIGS. 11A to 11C are cross-sectional views illustrating a nonvolatile semiconductor memory device according to a third embodiment;

FIG. 12 is a perspective view illustrating a central portion of a memory array region of the nonvolatile semiconductor memory device according to the third embodiment;

FIG. 13 is a partially-enlarged cross-sectional view illustrating a portion between gate electrodes of the nonvolatile semiconductor memory device according to the third embodiment;

FIG. 14A to FIG. 23B illustrate a method for manufacturing the nonvolatile semiconductor memory device according to the third embodiment; and

FIG. 24A to FIG. 37B illustrate a method for manufacturing a nonvolatile semiconductor memory device according to a fourth embodiment.

### DETAILED DESCRIPTION

According to one embodiment, a method for manufacturing a semiconductor memory device includes forming a first stacked body on a substrate by alternately stacking a first film and a second film, forming a second stacked body on the first stacked body by alternately stacking a third film and a fourth film, making a through-hole to pierce the second stacked body and the first stacked body by performing etching, an etching rate of the third film being lower than an etching rate of the first film in the etching, forming a charge storage film on an inner surface of the through-hole, and forming a semiconductor member in the through-hole. The first film and the second film are formed of mutually different materials. The third film and the fourth film are formed of mutually different materials. And, the first film and the third film are formed of mutually different materials.

Embodiments of the invention will now be described with reference to the drawings.

First, a first embodiment will be described.

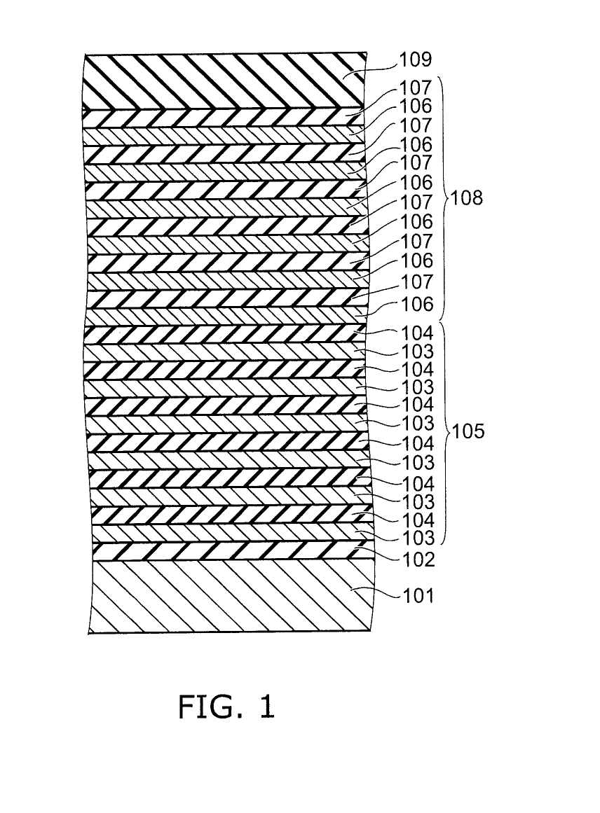

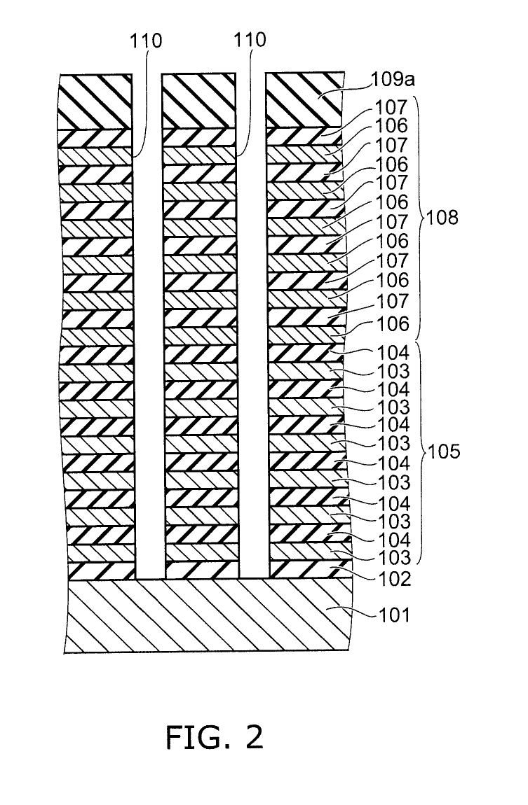

FIG. 1 and FIG. 2 are cross-sectional views of processes, illustrating a method for manufacturing a semiconductor memory device according to the embodiment.

For convenience of illustration in FIG. 1 and FIG. 2, the number of stacks of the films is illustrated as being less than the actual number. This is similar also for the other drawings described below.

The embodiment is a method for manufacturing an integrated circuit device, and in particular, is a method for manufacturing a semiconductor memory device, and in particular, is a method for manufacturing a stacked nonvolatile semiconductor memory device. The description of the embodiment focuses on the formation process of the stacked body and the process of making the through-holes of the method for manufacturing the stacked nonvolatile semiconductor memory device.

First, as illustrated in FIG. 1, a silicon substrate 101 made of, for example, monocrystalline silicon (Si) is prepared. Then, a silicon oxide film 102 made of silicon oxide (SiO₂) is formed on the silicon substrate 101. Then, a boron-doped polysilicon film 103 made of polysilicon having boron (B) introduced is stacked alternately with a non-doped polysilicon film 104 made of polysilicon without an introduced impurity. For example, the thickness of each of the films is 40 nm; and twenty layers are formed as total. Thereby, a stacked body 105 is formed on the silicon oxide film 102 by alternately stacking the boron-doped polysilicon film 103 and the non-doped polysilicon film 104.

Then, a boron-doped polysilicon film 106 is stacked alternately with a silicon oxide film 107. The silicon oxide film 107 is deposited by CVD (chemical vapor deposition) using a source material of TEOS (tetraethoxysilane, i.e., Si(OC₂H₅)₄). For example, the thickness of each of the films is 40 nm; and twenty layers are formed as total. Thereby, a stacked body 108 is formed on the stacked body 105 by alternately stacking the boron-doped polysilicon film 106 and the silicon oxide film 107. Subsequently, a hard mask film 109 made of, for example, silicon oxide is formed on the stacked body 108; and a resist pattern (not illustrated) is formed thereon.

Continuing as illustrated in FIG. 2, the processing substrate, in which the hard mask film 109 (referring to FIG. 1) and the resist pattern are formed on the stacked bodies 105 and 108 formed on the silicon substrate 101, is placed in a vacuum reaction chamber of a processing apparatus. Then, a hard mask pattern 109a is formed by patterning the hard mask film 109.

Then, the processing substrate is bombarded with reactive ions or active species (radicals) by generating discharge plasma by introducing a reactant gas into the vacuum reaction chamber. Thereby, the stacked body 108, the stacked body 105, and the silicon oxide film 102 are etched using the hard mask pattern 109a as a mask. At this time, this etching is performed with conditions in which the etching rate of the silicon oxide film 107 is lower than the etching rate of the non-doped polysilicon film 104. Although the etching conditions include the type of the etching gas, the pressure, the RF power, etc., the etching is performed, for example, using a halogen-based gas and a fluorocarbon-based gas as the etching gas. Thereby, a through-hole 110 is made to pierce the stacked body 108, the stacked body 105, and the silicon oxide film 102 by selectively removing the stacked body 108, the stacked body 105, and the silicon oxide film 102.

Continuing, a blocking insulating film, a charge storage film, and a tunneling insulating film (each of these is not illustrated) are formed on the inner surface of the through-hole 110. Then, a semiconductor member is provided by filling polysilicon having an introduced impurity into the interior of the through-hole 110. Thereby, a stacked semiconductor memory device is manufactured. In such a semiconductor memory device, the boron-doped polysilicon films 103 and 106 function as gate electrodes. A memory cell transistor is formed at each intersection between the semiconductor member and the gate electrodes. In such a case, the non-doped polysilicon film 104 of the stacked body 105 and the silicon oxide film 107 of the stacked body 108 may remain as-is to be used as the inter-electrode insulating films; or these films may be removed and an insulating material may be subsequently refilled to form films to be used as the inter-electrode insulating films. Or, the boron-doped polysilicon films 103 and 106 may be removed and a conductive material may be refilled to be used as the gate electrodes.

Operational effects of the embodiment will now be described.

In the process illustrated in FIG. 1 in the embodiment, the stacked body 105 is formed on the silicon substrate 101; and the stacked body 108 is formed thereon. In other words, the stacked body has a two-level configuration. Then, in the process illustrated in FIG. 2, the through-hole 110 is made in the stacked bodies 108 and 105 by performing etching with conditions in which the etching rate of the silicon oxide film 107 is lower than the etching rate of the non-doped polysilicon film 104.

Thereby, because the etching rate of the silicon oxide film 107 is relatively low when making the through-hole 110 in the stacked body 108 of the upper level, the silicon oxide film 107 is not etched much in the lateral direction; and the through-hole 110 can be made to be straight along the stacking direction (the vertical direction) of each of the films. Also, because the etching rate of the non-doped polysilicon film 104 is relatively high when making the through-hole 110 in the stacked body 105 of the lower level, the through-hole 110 can be made efficiently while suppressing the consumption of the hard mask pattern 109a. At this time, the through-hole 110 can be made to be straight along the vertical direction also in the stacked body 105 of the lower level because a sufficiently straight through-hole 110 is made in the stacked body 108 of the upper level and the stacked body 105 of the lower level is etched via the through-hole 110 made in the stacked body 108 of the upper level. As a result, a straight through-hole 110 can be made through the entirety of the stacked bodies 105 and 108.

Thus, according to the embodiment, the through-hole 110 can be made to be straight. Thereby, the design value of the distance between the through-holes 110 can be reduced while reliably preventing contact between the through-holes 110; and higher integration of the semiconductor memory device can be realized. In the stacked body 105 of the lower level, the through-hole 110 can be made with a high etching rate. Therefore, the consumption of the hard mask pattern 109a can be suppressed. Thereby, in the process illustrated in FIG. 1, the hard mask film 109 can be formed to be thin; and an ultra-fine pattern can be formed in the hard mask pattern 109a. For this reason as well, higher integration of the semiconductor memory device is easier. The semiconductor memory device can be manufactured efficiently because the through-hole 110 can be made with a high etching rate in the stacked body 105 of the lower level.

To ensure the straightness of the through-hole 110, it is necessary to suppress the etching in the lateral direction for the portion of the through-hole 110 initially etched, that is, the portion made in the stacked body 108 of the upper level, and to make the through-hole 110 to be straight. Therefore, it is favorable for the proportion of the thickness of the stacked body 108 to the total thickness of the stacked bodies 105 and 108 to be not less than 20%. On the other hand, to form a thin hard mask pattern 109a and increase the productivity of the semiconductor memory device, it is necessary for the etching rate to be high for the lower portion of the through-hole 110. Therefore, it is favorable for the proportion of the thickness of the stacked body 108 to the total thickness of the stacked bodies 105 and 108 to be not more than 80% and more favorable to be not more than 60%. Accordingly, it is favorable for the proportion recited above to be 20% to 80% and more favorable to be 20% to 60%.

Comparative examples of the first embodiment will now be described.

First, a first comparative example will be described.

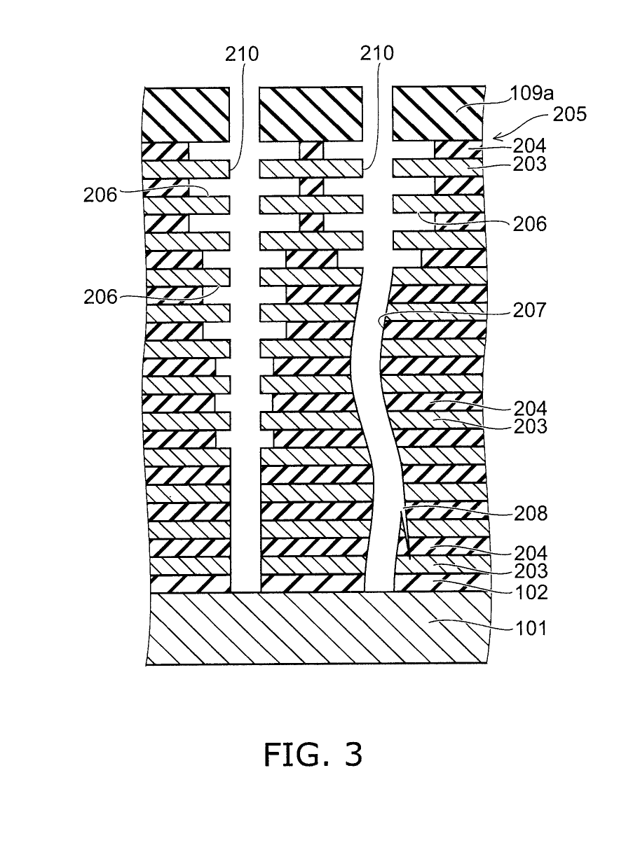

FIG. 3 is a cross-sectional view of a process, illustrating a method for manufacturing a semiconductor memory device according to the comparative example.

In the comparative example as illustrated in FIG. 3, a stacked body 205 is formed on the silicon oxide film 102 by alternately stacking a boron-doped silicon film 203 and a non-doped silicon film 204. Instead of two levels, a stacked body of one level is formed in the comparative example. A through-hole 210 is made by etching the stacked body 205.

Because the etching rate of the non-doped silicon film 204 is higher than the etching rate of the boron-doped silicon film 203 in the comparative example, the non-doped silicon film 204 is undesirably etched in the lateral direction as the through-hole 210 is made; and the non-doped silicon film 204 undesirably recedes from the inner surface of the through-hole 210. Thereby, a recess 206 is undesirably made in the inner surface of the through-hole 210. In particular, the receded amount of the non-doped silicon film 204 formed in the upper portion of the stacked body 205 increases because the time of being exposed to the etching is long. In the case where the non-doped silicon film 204 recedes from the inner surface of the through-hole 210, the ions irradiated for the etching undesirably have diffused reflections by the recess 206 that affect the subsequent etching. For example, the recession of the non-doped silicon film 204 is not limited to occurring uniformly in all directions parallel to the film surface; and there are many cases where the recession of the non-doped silicon film 204 is anisotropic in the film surface. In such a case, the diffused reflections of the ions also become anisotropic; a bend 207 occurs in the through-hole 210; and the through-hole 210 undesirably meanders. Also, there are cases where an irregularity 208 occurs due to the ions being concentratively irradiated onto one region of the side surface of the through-hole 210.

In the case where the through-hole 210 meanders, it is necessary to increase the design value of the distance between the through-holes 210 to reliably prevent contact between the through-holes 210. Therefore, higher integration of the semiconductor memory device becomes difficult. The characteristics of the memory cell transistor undesirably fluctuate due to the meandering of the through-hole 210 and due to the occurrence of the recess 206, the bend 207, the irregularity 208, etc.; and the reliability of the semiconductor memory device undesirably decreases.

A second comparative example will now be described.

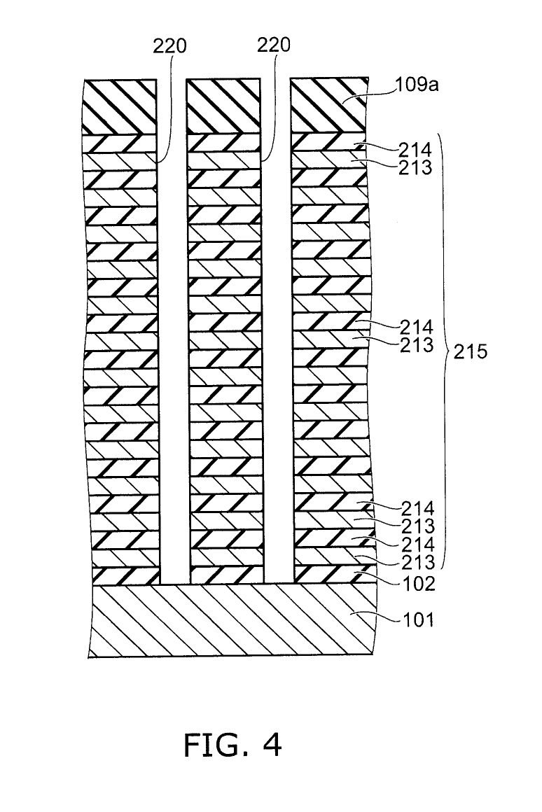

FIG. 4 is a cross-sectional view of a process, illustrating a method for manufacturing a semiconductor memory device according to the comparative example.

In the comparative example as illustrated in FIG. 4, a stacked body 215 is formed on the silicon oxide film 102 by alternately stacking a boron-doped silicon film 213 and a silicon oxide film 214. In the comparative example as well, instead of two levels, a stacked body of one level is formed similarly to the first comparative example described above. Then, a through-hole 220 is made by etching the stacked body 215.

Because the etching rate of the silicon oxide film 214 is lower than the etching rate of the boron-doped silicon film 213 in the comparative example, the silicon oxide film 214 is not etched much in the lateral direction when the through-hole 220 is made. Therefore, the through-hole 220 does not meander much; and the irregularity of the side surface does not occur easily.

However, in the comparative example, the consumed amount of the hard mask pattern 109a is large because the silicon oxide film 214 which has a low etching rate is provided throughout the total length of the stacked body 215 in the thickness direction. This is because the hard mask pattern is consumed because it is necessary to increase the energy of the ions of the etching to pattern the silicon oxide film. In the case where the aspect ratio of the through-hole is increased, it becomes necessary to increase the energy of the ions even more. Although reaction products of the boron-doped polysilicon film 213 have an effect of ensuring the remaining film amount of the hard mask pattern 109a, this effect also decreases in the case where the total film thickness of the silicon oxide films 214 is increased because the total film thickness of the boron-doped polysilicon films 213 is reduced by the amount that the total film thickness of the silicon oxide films 214 is increased. Therefore, in the comparative example, it is necessary to form a thick hard mask pattern 109a beforehand. Thereby, it becomes difficult to form an ultra-fine hard mask pattern 109a. Because the etching rate of the silicon oxide film 214 is low, a long period of time is unfortunately necessary to make the through-hole 220. As a result, the productivity of the semiconductor memory device is low.

A second embodiment will now be described.

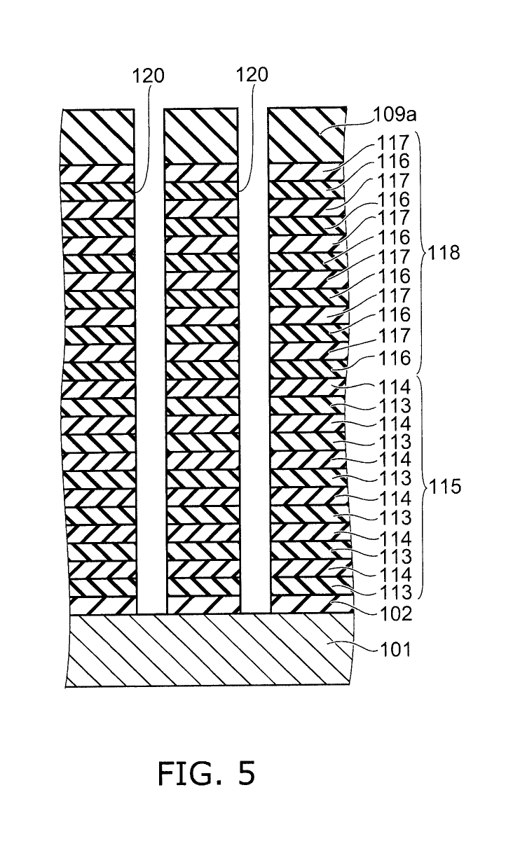

FIG. 5 is a cross-sectional view of a process, illustrating a method for manufacturing a semiconductor memory device according to the embodiment.

In the embodiment, the types of the films included in the stacked bodies are different from those of the embodiment described above.

In the embodiment as illustrated in FIG. 5, a stacked body 115 is formed on the silicon oxide film 102 by alternately stacking a silicon oxide film 113 and a silicon nitride 114; and a stacked body 118 is formed thereon by alternately stacking a silicon oxide film 116 and a non-doped polysilicon film 117. Then, the hard mask pattern 109a is formed on the stacked body 118. Continuing, a through-hole 120 is made in the stacked bodies 118 and 115 by performing etching using the hard mask pattern 109a as a mask with conditions in which the etching rate of the non-doped polysilicon film 117 is lower than the etching rate of the silicon nitride 114.

Then, the blocking insulating film, the charge storage film, and the tunneling insulating film (each of these is not illustrated) are formed on the inner surface of the through-hole 120; and a semiconductor member is provided in the interior of the through-hole 120. On the other hand, gate electrodes are formed by removing the silicon nitride 114 and the non-doped polysilicon film 117 and filling a conductive material into the space where these films are removed. Thereby, the semiconductor memory device is manufactured.

In the embodiment as well, the through-hole can be made in a straight line configuration similarly to the first embodiment described above. Thereby, higher integration can be realized while ensuring the productivity of the semiconductor memory device. Otherwise, the manufacturing method and the operational effects of the embodiment are similar to those of the first embodiment described above.

A third comparative example will now be described.

The comparative example is a comparative example of the second embodiment.

In the comparative example, a stacked body is formed on the silicon oxide film 102 by alternately stacking a silicon oxide film and a silicon nitride film. In other words, in the comparative example as well, a stacked body of one level instead of two levels is formed similarly to the first and second comparative examples described above. Then, the through-hole is made by etching the stacked body.

Because the etching rate of the silicon nitride film is higher than the etching rate of the silicon oxide film in the comparative example, a recess is undesirably made in the inner surface of the through-hole as the through-hole is made due to the silicon nitride film being etched in the lateral direction. Thereby, due to a principle similar to that of the first comparative example described above, a bend occurs in the through-hole; and the through-hole undesirably meanders. Also, there are cases where irregularities in the side surface of the through-hole occur. As a result, higher integration of the semiconductor memory device becomes difficult. Further, the reliability of the semiconductor memory device undesirably decreases.

In the first and second embodiments described above, a trench may be made to pierce the two stacked bodies. Via this trench, the non-doped polysilicon film 104 and the silicon oxide film 107, the boron-doped polysilicon films 103 and 106, or the silicon nitride 114 and the non-doped polysilicon film 117 may be removed and an insulating material or a conductive material may be refilled. Or, these films may be removed and the insulating material or the conductive material may be refilled via the through-hole 110.

Test examples comparing the embodiments and the comparative examples described above will now be described.

First, a first test example will be described.

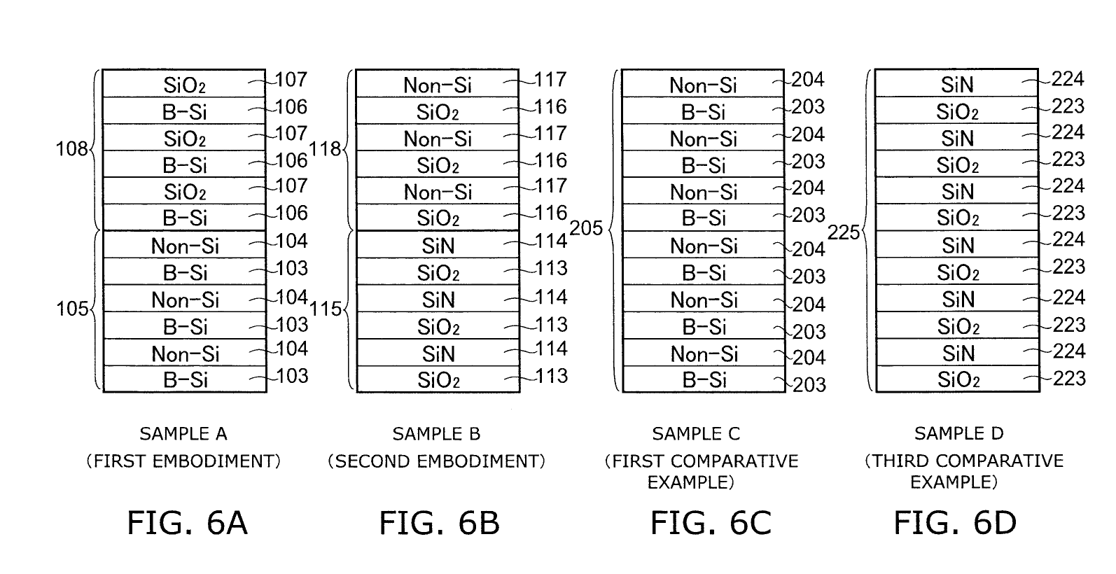

FIGS. 6A to 6D schematically illustrate samples evaluated for the test example.

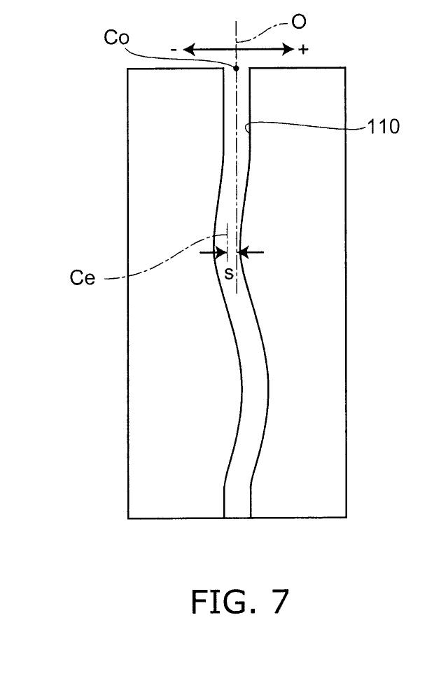

FIG. 7 illustrates the displacement amount of the through-hole.

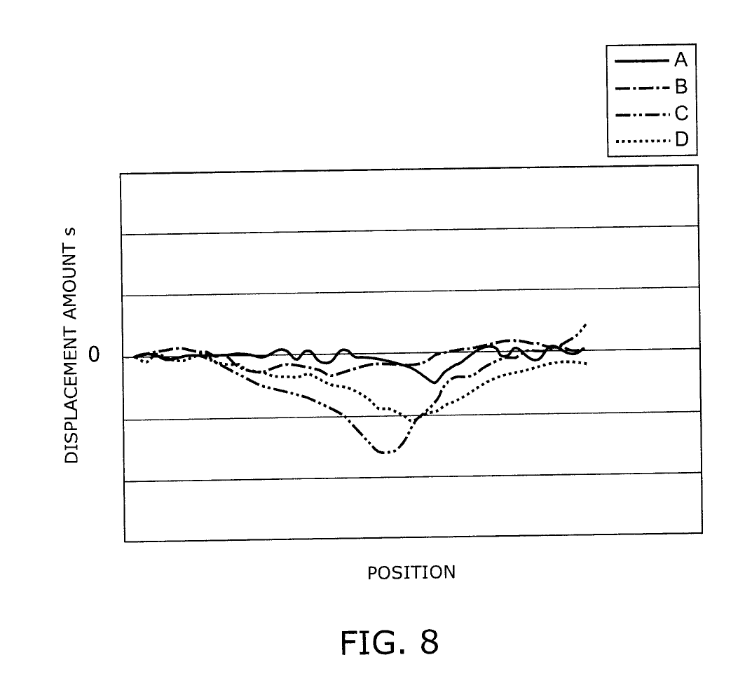

FIG. 8 is a graph illustrating the state of the meandering of the through-hole, where the horizontal axis illustrates the position in the vertical direction and the vertical axis illustrates the displacement amount of the through-hole.

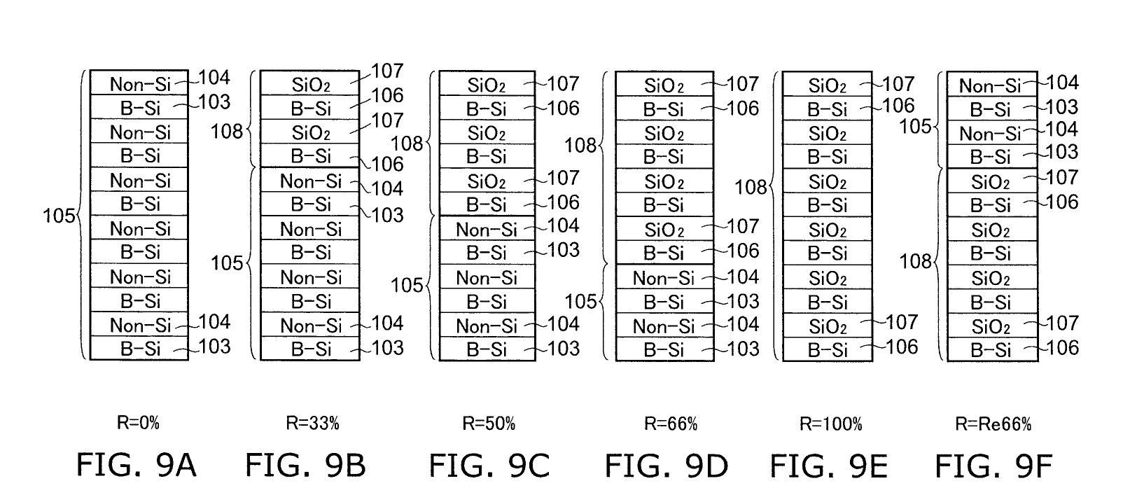

In FIGS. 6A to 6D, the boron-doped silicon film is represented by the symbol “B-Si;” the non-doped silicon film is represented by the symbol “Non-Si;” the silicon oxide film is represented by the symbol “SiO₂;” and the silicon nitride film is represented by the symbol “SiN.” This is similar also in FIGS. 9A to 9F described below.

As illustrated in FIGS. 6A to 6D, four types of samples were prepared for the test example.

The sample A illustrated in FIG. 6A corresponds to the first embodiment described above in which the stacked body 108 is formed on the stacked body 105, the stacked body 108 includes the boron-doped polysilicon film 106 stacked alternately with the silicon oxide film 107, and the stacked body 105 includes the boron-doped polysilicon film 103 stacked alternately with the non-doped polysilicon film 104. The total number of stacks of the stacked body 105 was twenty layers; and the total number of stacks of the stacked body 108 was twenty layers.

The sample B illustrated in FIG. 6B corresponds to the second embodiment described above in which the stacked body 118 is formed on the stacked body 115, the stacked body 118 includes the silicon oxide film 116 stacked alternately with the non-doped polysilicon film 117, and the stacked body 115 includes the silicon oxide film 113 stacked alternately with the silicon nitride 114. The total number of stacks of the stacked body 115 was twenty layers; and the total number of stacks of the stacked body 118 was twenty layers.

The sample C illustrated in FIG. 6C corresponds to the first comparative example described above in which the stacked body 205 is formed by alternately stacking the boron-doped silicon film 203 and the non-doped silicon film 204. The total number of stacks of the stacked body 205 was forty layers.

The sample D illustrated in FIG. 6D corresponds to the third comparative example described above in which a stacked body 225 is formed by alternately stacking a silicon oxide film 223 and a silicon nitride film 224. The total number of stacks of the stacked body 225 was forty layers.

Then, as illustrated in FIG. 7, a through-hole was made by etching these samples A to D. Here, a straight line extending in the vertical direction to pass through a center Co of the upper end portion of the through-hole 110 is taken as a reference line O; the center of the through-hole at any position in the vertical direction is taken as a center Ce; and the position of the center Ce using the reference line O as a reference is taken as the displacement amount s. Then, the meandering amount of the through-hole was evaluated by measuring the displacement amount s.

As illustrated in FIG. 8, the displacement amount s was smaller for the through-holes made in the sample A (the first embodiment) and the sample B (the second embodiment) than for the through-holes made in the sample C (the first comparative example) and the sample D (the third comparative example). In other words, the meandering amount was small.

A second test example will now be described.

FIGS. 9A to 9F schematically illustrate samples evaluated for the test example.

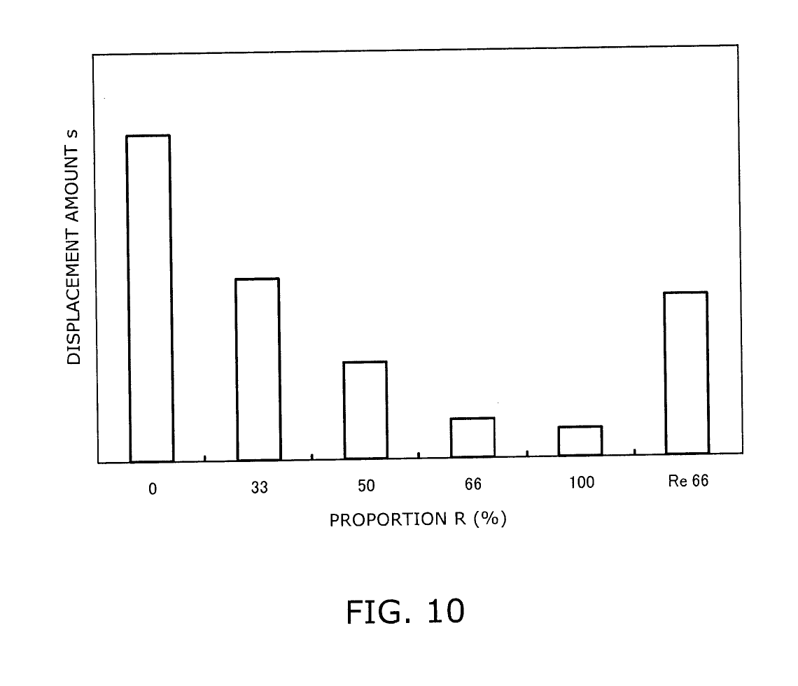

FIG. 10 is a graph illustrating the effect of the proportion of the thickness of the stacked body on the displacement amount of the through-hole, where the horizontal axis illustrates the proportion of the thickness of the stacked body of the upper level to the total thickness of the stacked bodies, and the vertical axis illustrates the maximum value of the displacement amount of the through-hole.

As illustrated in FIGS. 9A to 9F, multiple samples were constructed with different configurations of the films of the sample A by changing a proportion R of the thickness of the stacked body 108 of the upper level to the total thickness of the stacked body 105 of the lower level and the stacked body 108 of the upper level.

In the sample of R=0% as illustrated in FIG. 9A, the stacked body 108 of the upper level is not provided; and the sample includes only the stacked body 105 made of the boron-doped silicon film 103 and the non-doped silicon film 104. In other words, this sample is the same as the sample C of the first test example.

In the sample of R=33% as illustrated in FIG. 9B, the thickness of the stacked body 108 of the upper level is ⅓ of the thickness of the entirety; and the thickness of the stacked body 105 of the lower level is ⅔ of the thickness of the entirety.

In the sample of R=50% as illustrated in FIG. 9C, the thickness of the stacked body 108 of the upper level is ½ of the thickness of the entirety; and the thickness of the stacked body 105 of the lower level is ½ of the thickness of the entirety. In other words, this sample is the same as the sample A of the first test example.

In the sample of R=66% as illustrated in FIG. 9D, the thickness of the stacked body 108 of the upper level is ⅔ of the thickness of the entirety; and the thickness of the stacked body 105 of the lower level is ⅓ of the thickness of the entirety.

In the sample of R=100% as illustrated in FIG. 9E, the stacked body 105 of the lower level is not provided; and the sample includes the stacked body 108 made of the boron-doped polysilicon film 106 and the silicon oxide film 107. In other words, this sample corresponds to the second comparative example described above.

The sample of R=Re 66% as illustrated in FIG. 9F is a sample in which the upper and lower stacked bodies of the sample of R=66% illustrated in FIG. 9D are interchanged. In other words, the stacked body 108 made of the boron-doped silicon film 106 and the silicon oxide film 107 is disposed in the lower level; and the stacked body 105 made of the boron-doped silicon film 103 and the non-doped silicon film 104 is disposed in the upper level. The thickness of the stacked body 108 is ⅔ of the thickness of the entirety; and the thickness of the stacked body 105 is ⅓ of the thickness of the entirety.

As illustrated in FIG. 10, the maximum value of the displacement amount s decreased for the samples as the proportion R increased. In other words, the meandering amount of the through-hole decreased for the samples as the proportion of the stacked body of the upper level including the silicon oxide film having the relatively low etching rate increased. In the sample of R=66%, the meandering of the through-hole was substantially eliminated. Accordingly, this shows that it is favorable for the value of the proportion R to be large to suppress the meandering of the through-hole.

However, the film thickness of the hard mask pattern 109a (referring to FIG. 2) necessary to pattern the through-hole to the bottom portion of the stacked body undesirably increases as the total film thickness of the silicon oxide films is increased. For example, in the case where the film thickness of the hard mask pattern necessary to pattern the sample of R=0% is taken to be 1, the film thickness of the hard mask pattern necessary to pattern the sample of R=66% is 1.5 and the film thickness of the hard mask pattern necessary to pattern the sample of R=100% is 2.2.

The displacement amount s of the sample of R=66% (referring to FIG. 9D) was smaller than that of the sample of R=Re 66% (referring to FIG. 9F). Thereby, this shows that the effect of suppressing the meandering of the through-hole decreases as the etching rate of the stacked body of the upper level becomes higher than the etching rate of the stacked body of the lower level.

By performing tests similar to those of the second test example for the sample B described above, effects similar to those of the sample A were confirmed. For the first and second test examples, similar effects were confirmed even in the case where a trench was made instead of the through-hole in the stacked bodies.

The method for manufacturing the stacked semiconductor memory device including processes other than the formation processes of the stacked bodies and the process of making the through-hole will now be described in detail.

A third embodiment will now be described.

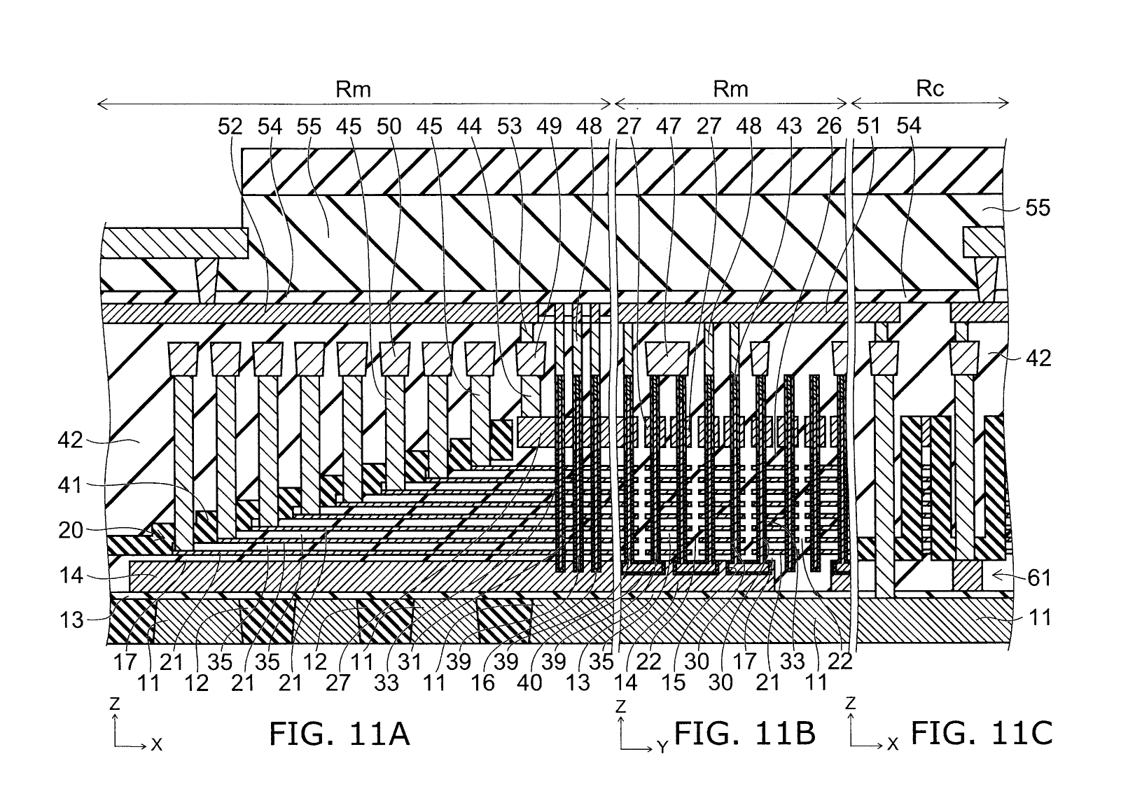

FIGS. 11A to 11C are cross-sectional views illustrating the nonvolatile semiconductor memory device according to the embodiment. FIG. 11A illustrates the end portion of the memory array region; FIG. 11B illustrates the central portion of the memory array region; and FIG. 11C illustrates the peripheral circuit region.

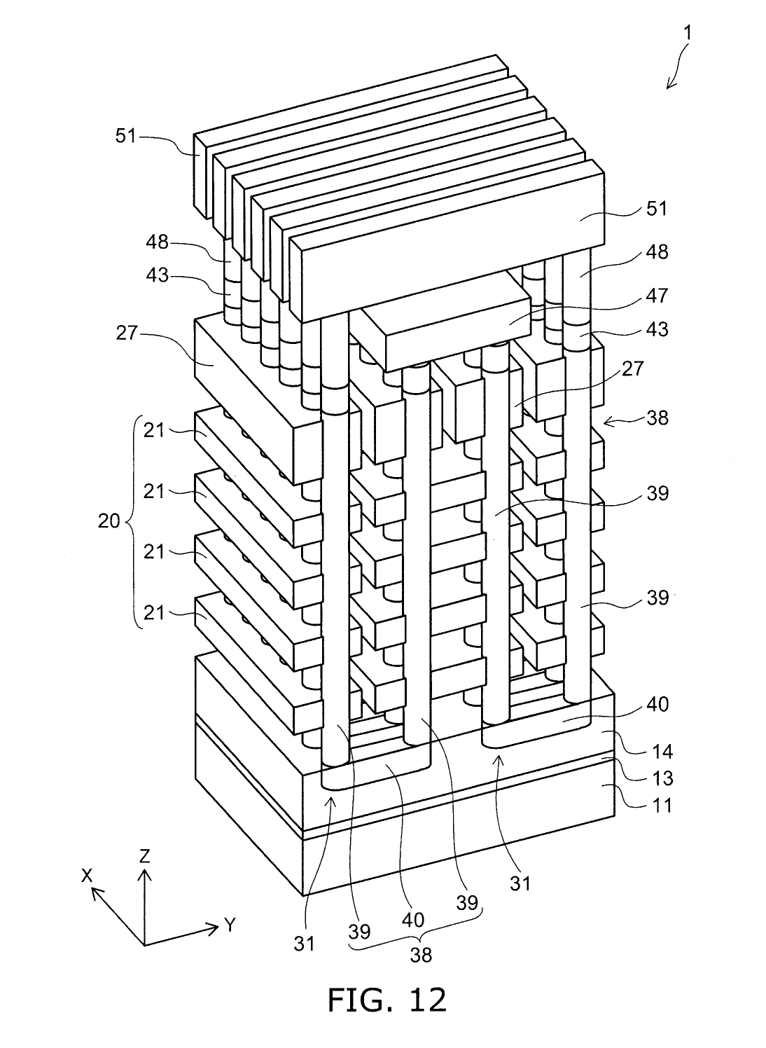

FIG. 12 is a perspective view illustrating the central portion of the memory array region of the nonvolatile semiconductor memory device according to the embodiment.

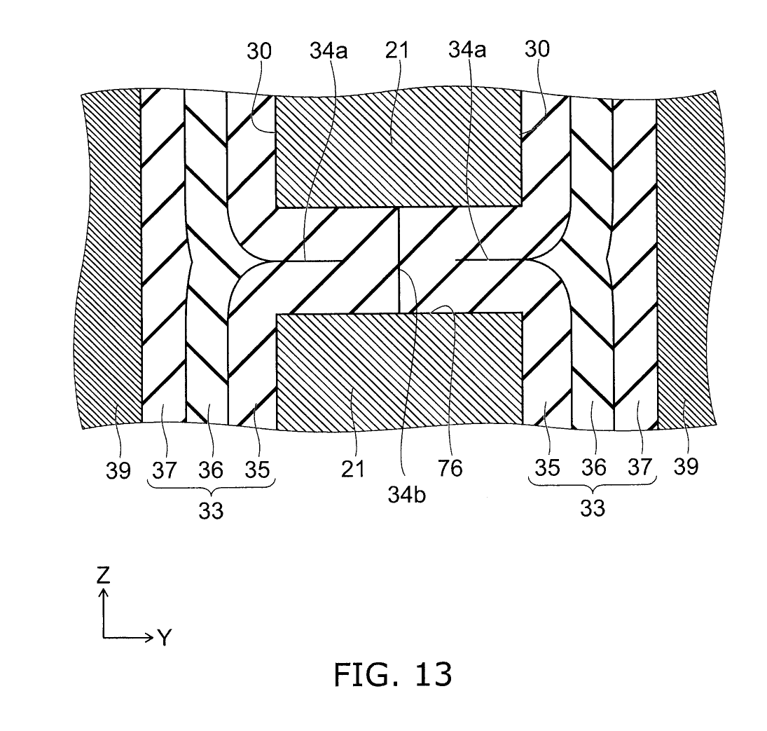

FIG. 13 is a partially-enlarged cross-sectional view illustrating a portion between the gate electrodes of the nonvolatile semiconductor memory device according to the embodiment.

For convenience of illustration in FIG. 12, as a general rule, only the conductive portions are illustrated, and the insulating portions are omitted.

A silicon substrate 11 is provided in the nonvolatile semiconductor memory device 1 (also referred to hereinbelow as simply the device 1) according to the embodiment as illustrated in FIGS. 11A to 11C. An STI (a shallow trench isolation) 12 is formed selectively in the upper layer portion of the silicon substrate 11. A memory array region Rm and a peripheral circuit region Rc are set in the device 1.

Hereinbelow, an XYZ orthogonal coordinate system is introduced for convenience of description in the embodiment and the fourth embodiment described below. In the coordinate system, two mutually orthogonal directions parallel to the upper surface of the silicon substrate 11 are taken as an X direction and a Y direction; and a direction orthogonal to both the X direction and the Y direction, i.e., the vertical direction, is taken as a Z direction.

First, the memory array region Rm will be described.

In the memory array region Rm as illustrated in FIGS. 11A to 11C and FIG. 12, a silicon oxide film 13 is formed on the silicon substrate 11; and a conductive material, e.g., a back gate electrode 14 made of silicon doped with phosphorus (phosphorus-doped silicon), is provided thereon. A recess 15 having a rectangular parallelepiped configuration extending in the Y direction is multiply made in the upper layer portion of the back gate electrode 14; and an insulating film having a low dielectric constant, e.g., a silicon oxide film 16, is provided on the inner surface of the recess 15. A silicon oxide film 17 is provided on the back gate electrode 14.

A stacked body 20 is provided on the silicon oxide film 17. Multiple gate electrodes 21 are provided in the stacked body 20. The gate electrode 21 is made of silicon having boron introduced (boron-doped silicon); the configuration thereof is a band configuration extending in the X direction; and the gate electrode 21 is arranged in a matrix configuration along the Y direction and the Z direction. The end portion of the stacked body 20 is patterned into a stairstep configuration; and the gate electrodes 21 are arranged in the Z direction to be included respectively in the levels.

An insulating plate member 22 made of, for example, silicon oxide is provided between the gate electrodes 21 adjacent to each other in the Y direction. The insulating plate member 22 has a plate configuration spreading in the X direction and the Z direction to pierce the stacked body 20. A blocking insulating film 35 described below (referring to FIG. 13) is filled between the gate electrodes 21 adjacent to each other in the Z direction. A silicon oxide film 26 is provided on the stacked body 20; and a control electrode 27 made of boron-doped silicon extending in the X direction is multiply provided thereon.

Then, multiple through-holes 30 extending in the Z direction are made in the stacked body 20, the silicon oxide film 26, and the control electrode 27. The through-holes 30 are arranged in a matrix configuration along the X direction and the Y direction and pierce the control electrode 27, the silicon oxide film 26, and the stacked body 20 to reach both of the Y-direction end portions of the recess 15. Thereby, a pair of the through-holes 30 adjacent to each other in the Y direction communicate with each other by the recess 15 and are included in one U-shaped hole 31. Each of the through-holes 30 has, for example, a circular columnar configuration; and the configuration of each of the U-shaped holes 31 is substantially U-shaped. Each of the gate electrodes 21 is pierced by two columns of the through-holes 30 arranged along the X direction. Because the arrangement of the recesses 15 and the arrangement of the gate electrodes 21 in the Y direction have the same arrangement period with the phases shifted by half a period, the two columns of the through-holes 30 that pierce each of the gate electrodes 21 are configured to belong to mutually different U-shaped holes 31.

As illustrated in FIGS. 11A to 11C and FIG. 13, the blocking insulating film 35 is provided on the inner surface of the U-shaped hole 31. The blocking insulating film 35 is a film in which current substantially does not flow even in the case where a voltage in the range of the drive voltage of the device 1 is applied. The blocking insulating film 35 is formed of a high dielectric constant material, e.g., silicon oxide, e.g., a material having a dielectric constant higher than the dielectric constant of the material of a charge storage film 36 described below. The blocking insulating film 35 extends around from the inner surface of the through-hole 30 onto the upper surface and the lower surface of the gate electrode 21 to cover the upper surface and the lower surface of the gate electrode 21.

In the embodiment, a portion of the blocking insulating film 35 disposed on the upper surface of one of the gate electrodes 21 contacts a portion of the blocking insulating film 35 disposed on the lower surface of one other of the gate electrodes 21 disposed in one level above the one of the gate electrodes 21; and a seam 34a is formed at the contact surface thereof. Thereby, the blocking insulating film 35 fills the space between the gate electrodes 21 adjacent to each other in the Z direction. The blocking insulating film 35 entering the space between the gate electrodes 21 by extending from the inner surface of one of the through-holes 30 around onto the upper surface and the lower surface of the gate electrodes 21 is in contact with the blocking insulating film 35 entering the space between the same gate electrodes 21 by extending from the inner surface of an adjacent through-hole 30 around onto the upper surface and the lower surface of the same gate electrodes 21; and a seam 34b is formed at the contact surface thereof. The microstructure of the blocking insulating film 35 at the seams 34a and 34b is discontinuous; and the seams 34a and 34b can be observed by performing chemical liquid processing, etc., on a cross section that includes the seams 34a and 34b.

The charge storage film 36 is provided on the blocking insulating film 35. The charge storage film 36 is a film capable of storing charge, e.g., a layer including trap sites of electrons, e.g., a silicon nitride film. In the embodiment, the charge storage film 36 is disposed only inside the U-shaped hole 31 and does not enter the space between the gate electrodes 21 adjacent to each other in the Z direction.

A tunneling insulating film 37 is provided on the charge storage film 36. Although the tunneling insulating film 37 normally is insulative, the tunneling insulating film 37 is a film in which a tunneling current flows when a prescribed voltage within the range of the drive voltage of the device 1 is applied. The tunneling insulating film 37 is formed of, for example, silicon oxide. The tunneling insulating film 37 also is disposed only inside the U-shaped hole 31 and does not enter the space between the gate electrodes 21 adjacent to each other in the Z direction. A memory film 33 is formed by stacking the blocking insulating film 35, the charge storage film 36, and the tunneling insulating film 37.

A U-shaped pillar 38 is formed as the semiconductor member by filling polysilicon having an impurity, e.g., phosphorus, introduced into the U-shaped hole 31. The configuration of the U-shaped pillar 38 is U-shaped reflecting the configuration of the U-shaped hole 31. The U-shaped pillar 38 contacts the tunneling insulating film 37. Of the U-shaped pillar 38, the portions disposed inside the through-holes 30 become silicon pillars 39; and the portion disposed inside the recess 15 becomes a connection member 40. The silicon pillar has a circular columnar configuration reflecting the configuration of the through-hole 30; and the connection member 40 has a rectangular parallelepiped configuration reflecting the configuration of the recess 15. The polysilicon may form the U-shaped pillar 38 with a columnar configuration completely filled into the U-shaped hole 31 or may form the U-shaped pillar 38 with a pipe-like configuration by filling while leaving a cavity along the central axis.

As illustrated in FIGS. 11A to 11C and FIG. 12, a silicon nitride film 41 is provided on the side surface of the stacked body 20 patterned into the stairstep configuration, on the side surface of the silicon oxide film 26, and on the side surface of the control electrode 27. The silicon nitride film 41 is formed into a stairstep configuration reflecting the configuration of the end portion of the stacked body 20. An inter-layer insulating film 42 made of, for example, silicon oxide is provided on the control electrode 27 and on the silicon nitride film 41 to bury the stacked body 20.

A plug 43 and contacts 44 to 45 are buried in the inter-layer insulating film 42. The plug 43 is disposed in the region directly above the silicon pillar 39 and is connected to the silicon pillar 39. The contact 44 is disposed in the region directly above one X-direction end portion of the control electrode 27 and is connected to the control electrode 27. The contact 45 is disposed in the region directly above one X-direction end portion of the gate electrode 21 and is connected to the gate electrode 21.

A source line 47, a plug 48, and interconnects 49 and 50 are buried in the portion of the inter-layer insulating film 42 higher than the plug 43 and the contacts 44 and 45. The source line 47 extends in the X direction and is connected to one of a pair of the silicon pillars 39 belonging to the U-shaped pillar 38 via the plug 43. The plug 48 is connected to the other of the pair of the silicon pillars 39 belonging to the U-shaped pillar 38 via the plug 43. The interconnects 49 and 50 extend in the Y direction and are connected to the contacts 44 and 45 respectively.

A bit line 51 extending in the Y direction is provided on the inter-layer insulating film 42 and is connected to the plug 48. An interconnect 52 is provided on the inter-layer insulating film 42 and is connected to the interconnect 49 via a plug 53. Prescribed interconnects, etc., are buried in a silicon nitride film 54 and an inter-layer insulating film 55 provided on the inter-layer insulating film 42 to bury the bit line 51 and the interconnect 52.

On the other hand, in the peripheral circuit region Rc as illustrated in FIG. 11C, a transistor 61, etc., are formed in the upper layer portion of the silicon substrate 11; the inter-layer insulating film 42, the silicon nitride film 54, and the inter-layer insulating film 55 are provided on the silicon substrate 11; and prescribed interconnects, etc., are buried in the interiors thereof. Although the horizontal axis of FIG. 11C is taken to be the X direction, the horizontal axis may be the Y direction.

In the device 1, memory cell transistors are formed at the intersections between the gate electrodes 21 and the silicon pillars 39; and selection transistors are formed at the intersections between the control electrodes 27 and the silicon pillars 39. Thereby, multiple memory cell transistors are connected in series with each other between the bit line 51 and the source line 47 to form a memory string connected between the selection transistors on both sides thereof.

A method for manufacturing a nonvolatile semiconductor memory device according to the embodiment will now be described.

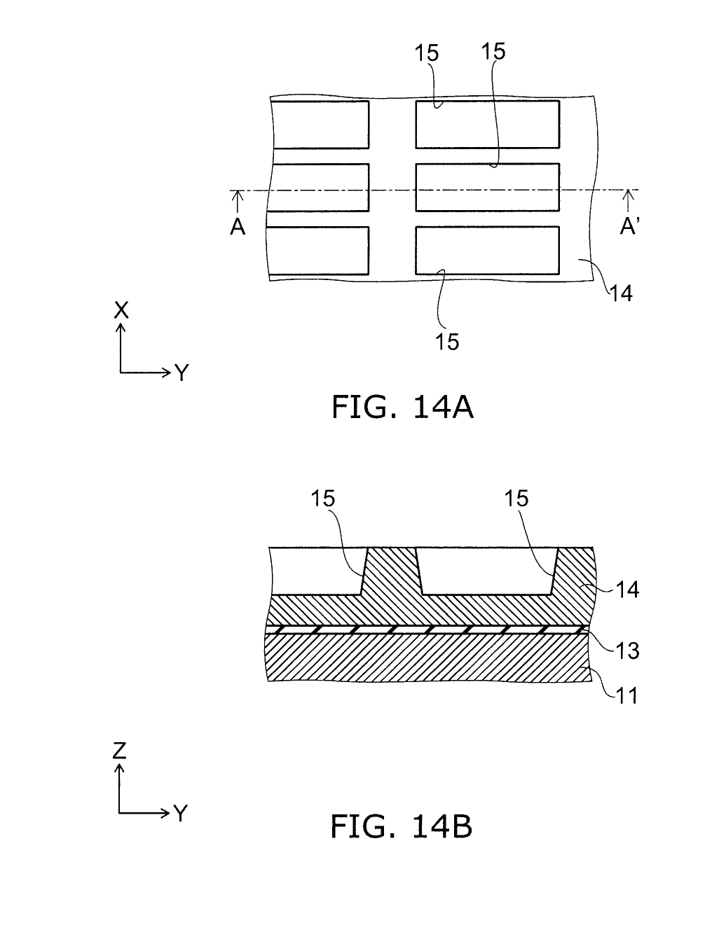

FIG. 14A to FIG. 23B illustrate the method for manufacturing the nonvolatile semiconductor memory device according to the embodiment. Drawing A of each of the drawings is a process plan view; and drawing B of each of the drawings is a process cross-sectional view along line A-A′ of drawing A.

FIG. 14A to FIG. 23B illustrate the memory array region Rm of the device 1.

First, as illustrated in FIGS. 11A to 11C, the silicon substrate 11 is prepared. Then, the STI 12 is selectively formed in the upper layer portion of the silicon substrate 11. Continuing, the transistor 61 is formed in the peripheral circuit region Rc. The silicon oxide film 13 is formed on the upper surface of the silicon substrate 11 of the memory array region Rm.

Then, in the memory array region Rm as illustrated in FIGS. 14A and 14B, the back gate electrode 14 is formed by forming a film made of polysilicon doped with phosphorus and by patterning. Then, the recess 15 is made in the upper surface of the back gate electrode 14 with a rectangular parallelepiped configuration having its longitudinal direction in the Y direction by photolithography. The recess 15 is made in multiple regions to be arranged in a matrix configuration along the X direction and the Y direction.

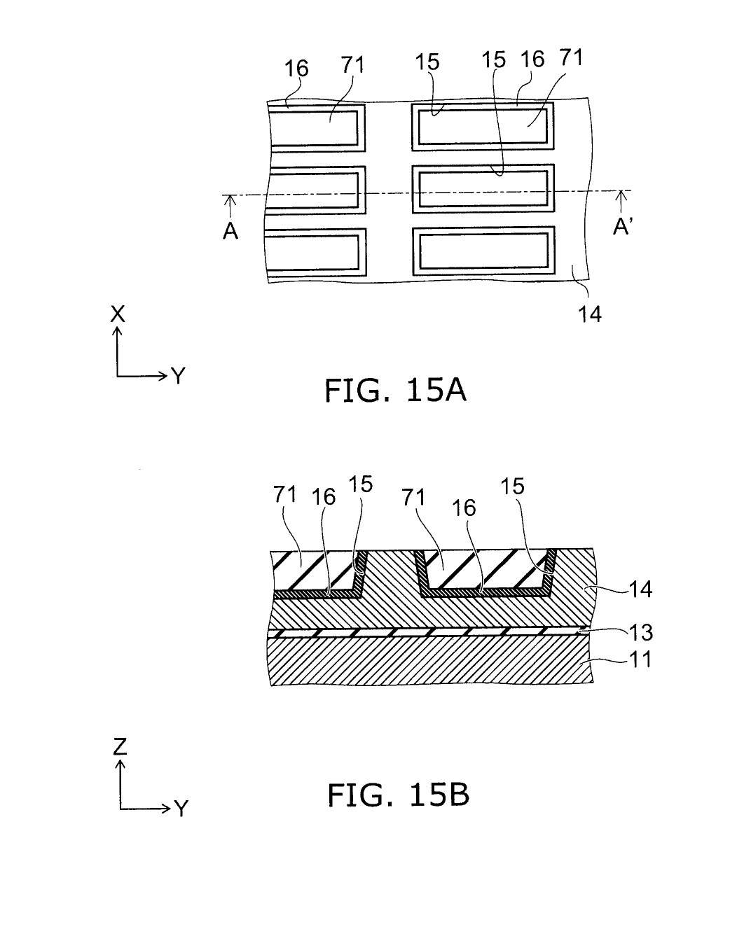

Continuing as illustrated in FIGS. 15A and 15B, the silicon oxide film 16 is formed on the inner surface of the recess 15. Then, silicon without an introduced impurity (non-doped silicon) is deposited on the entire surface; and the entire surface is etched. Thereby, the non-doped silicon is removed from the upper surface of the back gate electrode 14 and allowed to remain inside the recess 15. As a result, the upper surface of the back gate electrode 14 is exposed in the region between the recesses 15; and a non-doped silicon member 71 is filled into the recess 15.

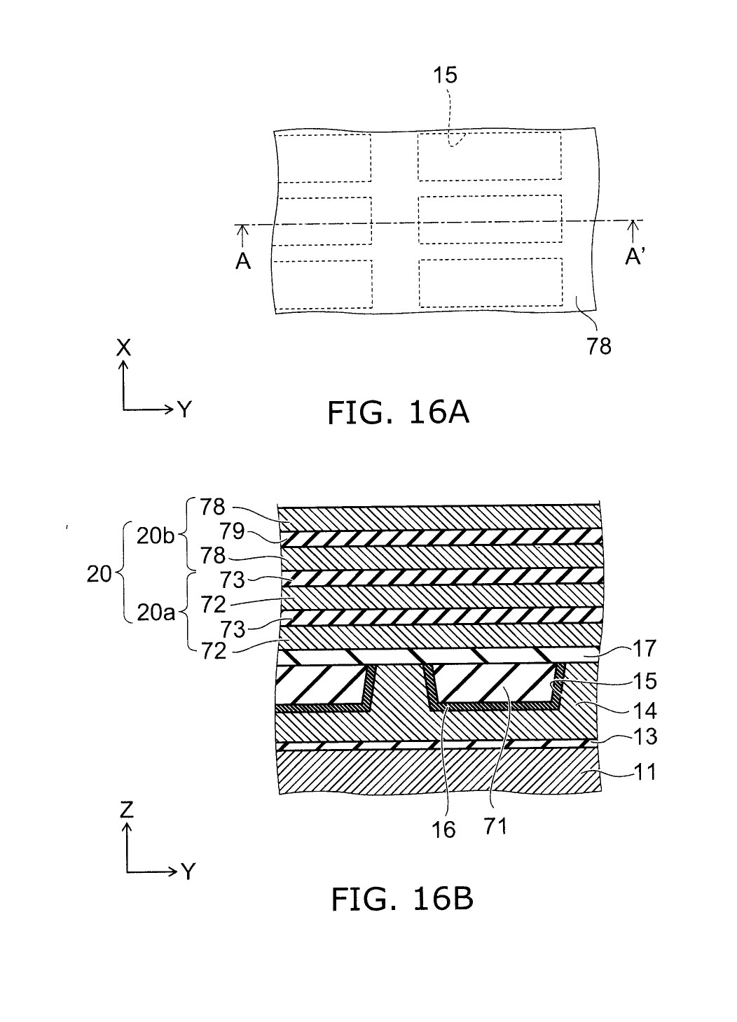

Then, as illustrated in FIGS. 16A and 16B, the silicon oxide film 17 is formed on the entire surface of the back gate electrode 14. The film thickness of the silicon oxide film 17 is set to be sufficient to ensure the breakdown voltage between the back gate electrode 14 and the gate electrode 21 of the lowermost level of the gate electrodes 21 formed on the silicon oxide film 17 in a subsequent process. Then, a boron-doped polysilicon film 72 having boron introduced is stacked alternately with a non-doped polysilicon film 73 without an introduced impurity. Thereby, a stacked body 20a is formed on the silicon oxide film 17 by alternately stacking the boron-doped polysilicon film 72 and the non-doped polysilicon film 73. Then, a boron-doped polysilicon film 78 is stacked alternately with a silicon oxide film 79. Thereby, a stacked body 20b is formed on the stacked body 20a by alternately stacking the boron-doped polysilicon film 78 and the silicon oxide film 79. The stacked body 20 includes the stacked body 20a and the stacked body 20b. At this time, it is favorable for the proportion of the thickness of the stacked body 20b to the thickness of the entire stacked body 20 to be 20% to 80% and more favorable to be 20% to 60%.

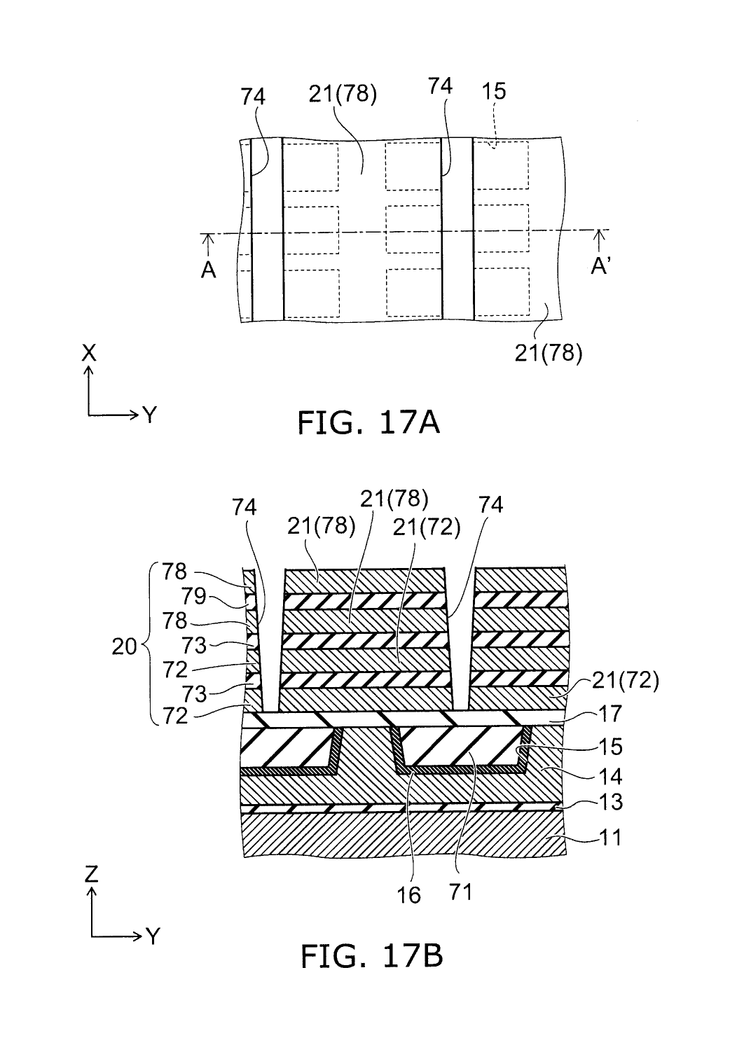

Continuing as illustrated in FIGS. 17A and 17B, multiple trenches 74 extending in the X direction are made in the stacked body 20 from the upper surface side thereof by performing photolithography and etching. At this time, etching is performed with conditions in which the etching rate of the silicon oxide film 79 is lower than the etching rate of the non-doped polysilicon film 73. For example, etching is performed using a halogen-based gas and a fluorocarbon-based gas as the etching gas. Thereby, as described in regard to the first embodiment described above, the meandering of the trench 74 can be suppressed; and the trench 74 can be made to be straight. Each of the trenches 74 is made to pierce the stacked body 20 in the Z direction and pass through the region directly above the Y-direction central portion of the recess 15. Thereby, the boron-doped silicon layers 78 and 72 are divided into the multiple gate electrodes 21.

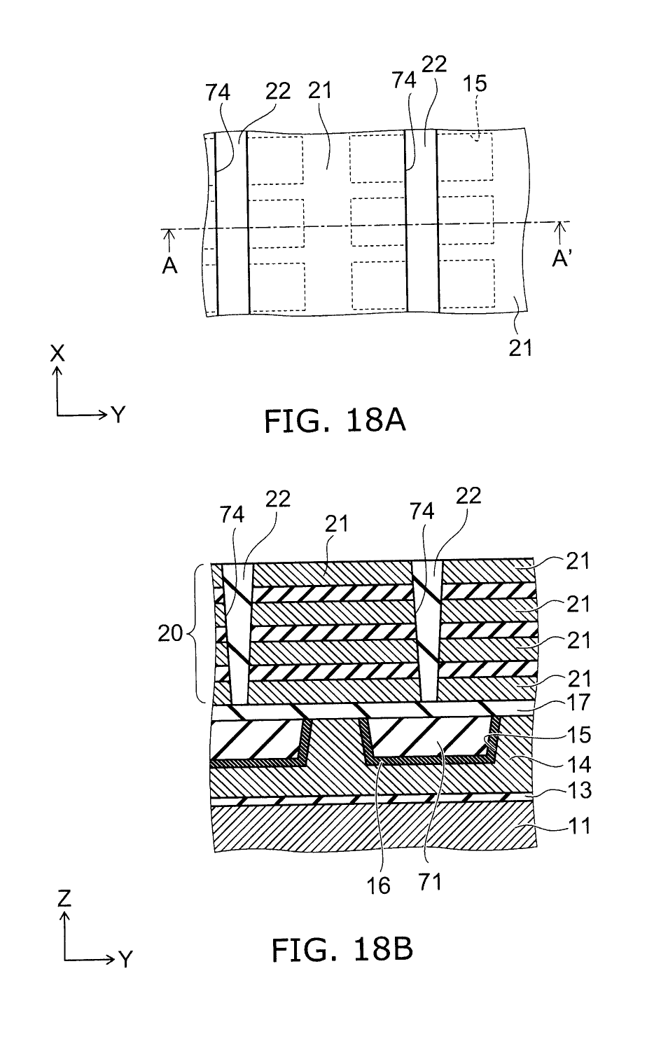

Then, as illustrated in FIGS. 18A and 18B, an insulating material such as silicon oxide is deposited on the entire surface.

At this time, the insulating material is filled also into the trench 74. Subsequently, the entire surface is etched to remove the insulating material from the upper surface of the stacked body 20 and allow the insulating material to remain inside the trench 74. Thereby, the insulating plate member 22 is formed inside the trench 74 with a plate configuration spreading in the X direction and the Z direction. Also, the gate electrode 21 of the uppermost level is exposed at the upper surface of the stacked body 20.

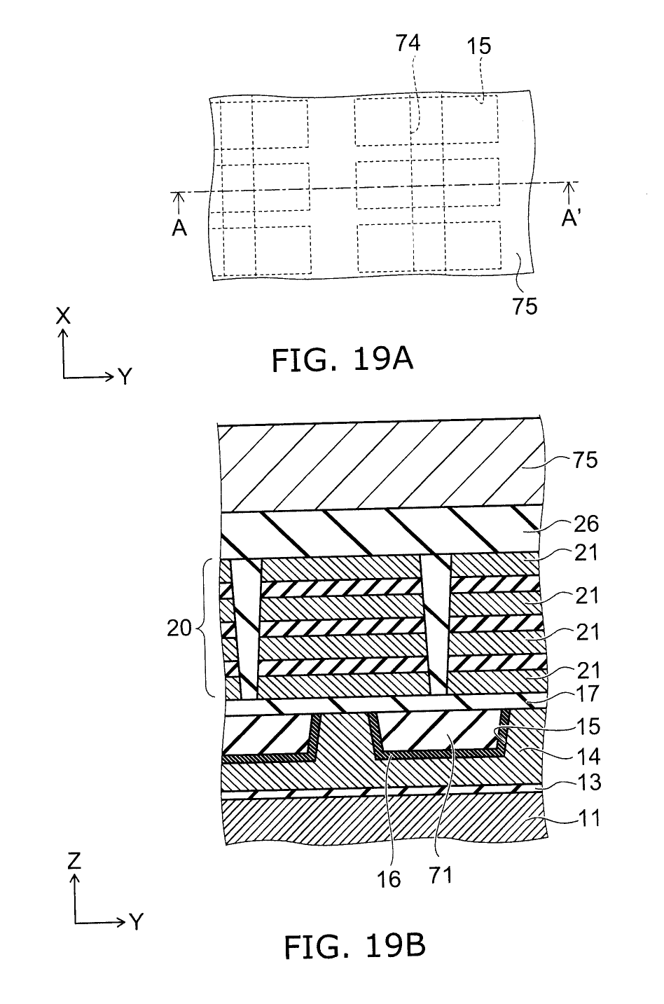

Continuing as illustrated in FIGS. 19A and 19B, the silicon oxide film 26 is formed on the stacked body 20; and a boron-doped polysilicon film 75 is formed thereon. At this time, the film thickness of the silicon oxide film 26 is a film thickness that can sufficiently ensure the breakdown voltage between the gate electrode 21 of the uppermost level and the boron-doped polysilicon film 75.

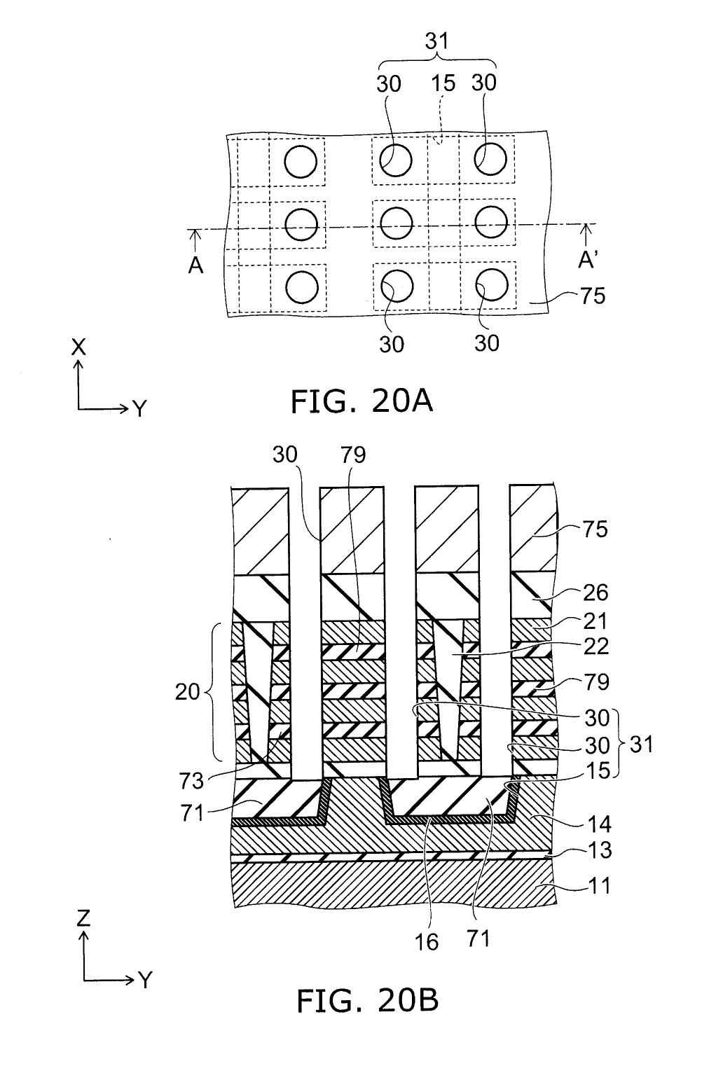

Then, as illustrated in FIGS. 20A and 20B, the multiple through-holes 30 extending in the Z direction are made to pierce the boron-doped polysilicon film 75, the silicon oxide film 26, and the stacked body 20 by performing photolithography and etching. At this time, the etching is performed with conditions in which the etching rate of the silicon oxide film 79 is lower than the etching rate of the non-doped polysilicon film 73. Thereby, the through-hole 30 can be made to be straight. The through-hole 30 is made to be circular as viewed from the Z direction. The through-hole 30 is arranged in a matrix configuration along the X direction and the Y direction; and a pair of the through-holes 30 adjacent to each other in the Y direction reaches both of the Y-direction end portions of the recess 15. Thereby, the U-shaped hole 31 is made by the pair of the through-holes 30 communicating with both ends of one of the recesses 15.

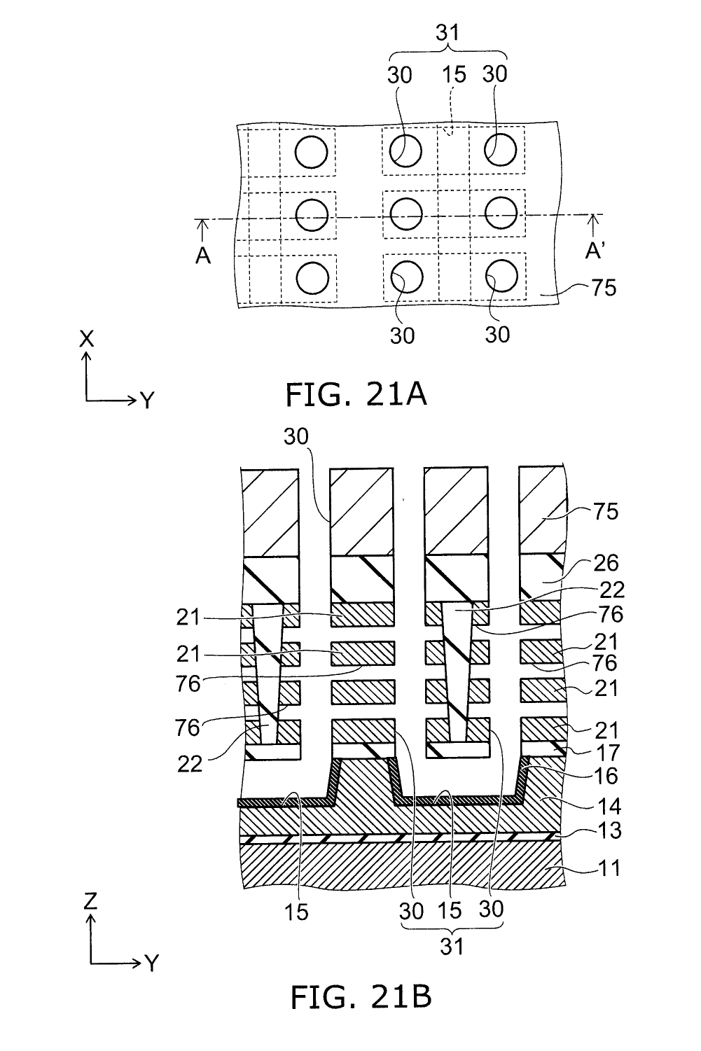

Continuing as illustrated in FIGS. 21A and 21B, wet etching is performed via the through-hole 30. This wet etching is performed using, for example, an alkaline etchant. Thereby, the non-doped polysilicon film 73 inside the stacked body 20 (referring to FIG. 20B) and the non-doped silicon member 71 inside the recess 15 (referring to FIG. 20B) are removed. Then, wet etching is performed again via the through-hole 30. This wet etching is performed using an etchant containing, for example, hydrofluoric acid. Thereby, the silicon oxide film 79 is removed. Thus, in the embodiment, the non-doped polysilicon film 73 and the silicon oxide film 79 are removed by performing wet etching via the through-hole 30.

In such a case, by appropriately selecting the etchant, a high etching selectivity can be realized between the boron-doped silicon and the non-doped silicon and between the boron-doped silicon and the silicon oxide. Therefore, the boron-doped polysilicon film 75 and the gate electrodes 21 made of the boron-doped polysilicon films 72 remain substantially without being etched. As a result, a gap 76 forms between the gate electrodes 21 in the Z direction. At this time, the gate electrodes 21 are supported by the insulating plate member 22 having the plate configuration. Although the portions of the gate electrodes 21 positioned between the U-shaped holes 31 are illustrated floating in the air in FIG. 21B, these are actually linked to portions of the gate electrodes 21 bonded to the insulating plate member 22 at positions shifted in the X direction (in FIG. 21B, the direction perpendicular to the page surface).

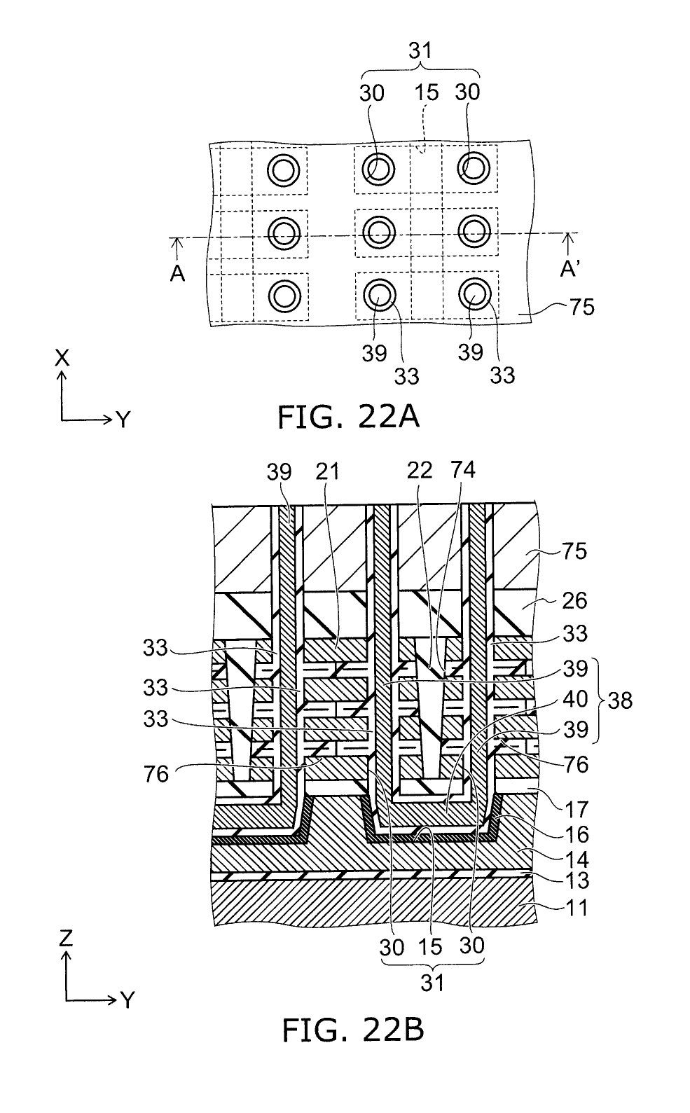

Then, as illustrated in FIGS. 22A and 22B and FIG. 3, silicon oxide is deposited by, for example, ALD (atomic layer deposition). The blocking insulating film 35 is deposited on the inner surface of the U-shaped hole 31 by the silicon oxide entering the U-shaped hole 31. Also, the blocking insulating film 35 is deposited on the inner surface of the gap 76, i.e., the upper surface and the lower surface of the gate electrode 21 and the surface of the insulating plate member 22 exposed inside the gap 76, by the silicon oxide entering the gap 76 via the through-hole 30. Thereby, an insulating film is formed inside the gap 76.

In the embodiment, the deposited amount of the blocking insulating film 35 is set to be not less than half of the distance between the gate electrodes 21 in the Z direction. Thereby, as illustrated in FIG. 13, the blocking insulating film 35 completely fills the interior of the gap 76; the portion of the blocking insulating film 35 formed on the upper surface of one of the gate electrodes 21 contacts the portion of the blocking insulating film 35 formed on the lower surface of the gate electrode 21 disposed in one level above the one of the gate electrodes 21; and the seam 34a is formed at the contact surface between the two portions. The blocking insulating films 35 entering the same gap 76 via mutually-adjacent through-holes 30 contact each other inside the gap 76; and the seam 34b is formed at the contact surface thereof.

Then, silicon nitride is deposited. Thereby, the charge storage film 36 is formed on the blocking insulating film 35. At this time, the charge storage film 36 does not enter the gap 76 and is formed only inside the U-shaped hole 31 because the blocking insulating film 35 fills the interior of the gap 76. Then, the silicon oxide film is deposited. Thereby, the tunneling insulating film 37 is formed on the charge storage film 36. Also, the tunneling insulating film 37 does not enter the gap 76 and is formed only inside the U-shaped hole 31. The memory film 33 is formed of the blocking insulating film 35, the charge storage film 36, and the tunneling insulating film 37.

Continuing, polysilicon containing an impurity, e.g., phosphorus, is filled into the U-shaped hole 31. Thereby, the U-shaped pillar 38 is formed inside the U-shaped hole 31. The portions of the U-shaped pillar 38 disposed inside the through-holes 30 become the silicon pillars 39 extending in the Z direction; and the portion disposed inside the recess 15 becomes the connection member 40 extending in the Y direction. Subsequently, the entire surface is etched to expose the boron-doped polysilicon film 75 by removing the polysilicon, the tunneling insulating film 37, the charge storage film 36, and the blocking insulating film 35 deposited on the boron-doped polysilicon film 75.

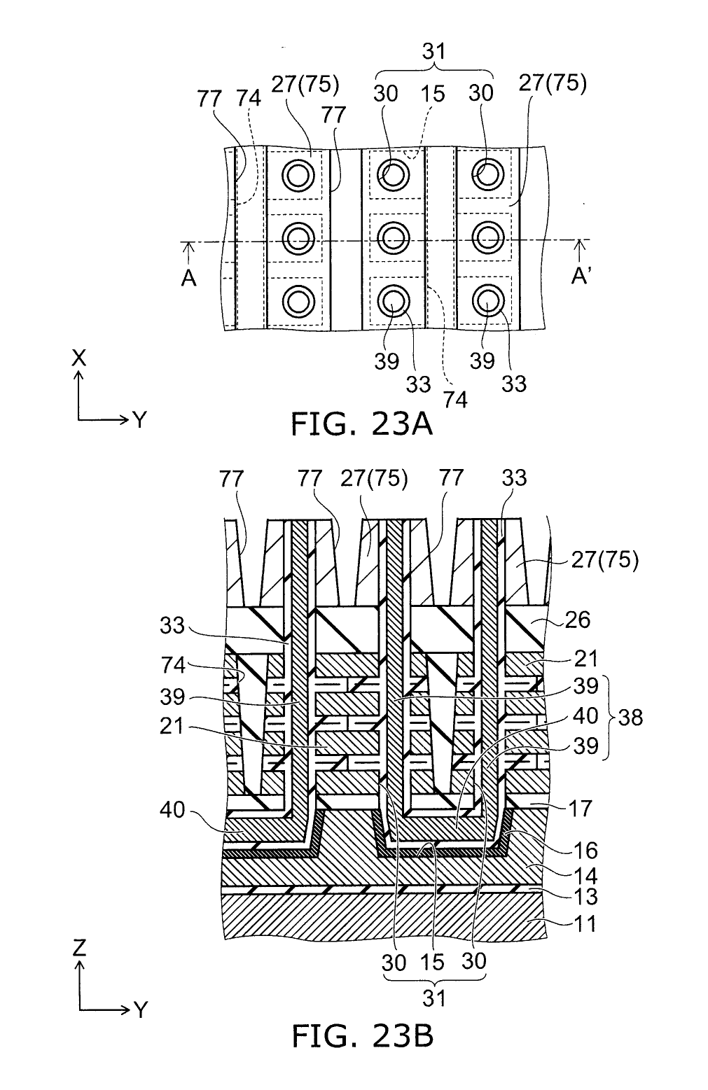

Then, as illustrated in FIGS. 23A and 23B, slits 77 extending in the X direction are multiply made in the boron-doped polysilicon film 75 from the upper surface side thereof by performing photolithography and etching. At this time, the slits 77 are made between the columns made of the multiple through-holes 30 arranged in the X direction; and each of the slits 77 pierces the boron-doped polysilicon film 75 to reach the silicon oxide film 26. Thereby, the boron-doped polysilicon film 75 becomes the multiple control electrodes 27 extending in the X direction by being divided for every column made of the multiple through-holes 30 arranged in the X direction. Subsequently, silicon oxide is filled into the slits 77.

Continuing as illustrated in FIGS. 11A to 11C and FIG. 12, the end portions of the stacked body 20 and the boron-doped polysilicon film 75 are patterned into a stairstep configuration by forming a resist mask (not illustrated) on the stacked body 20 and then alternately performing slimming of the resist mask and etching using the resist mask as a mask. Then, the silicon nitride film 41 is formed on the side surfaces of the boron-doped polysilicon film 75 and the stacked body 20; and the inter-layer insulating film 42 buries the entirety. Then, the contacts 44 and 45 are formed using the silicon nitride film 41 as a stopper while forming the plug 43 inside the inter-layer insulating film 42. Subsequently, the source line 47 and the interconnects 49 and 50 are formed on the inter-layer insulating film 42; and the plug 48 is formed by further depositing the inter-layer insulating film 42. Then, the bit line 51 and the interconnect 52 are formed on the inter-layer insulating film 42; the silicon nitride film 54 is formed thereon; and the inter-layer insulating film 55 is formed thereon. Thus, the nonvolatile semiconductor memory device 1 according to the embodiment is manufactured.

Operational effects of the embodiment will now be described.

In the embodiment, the stacked body 20 has a two-level configuration including the stacked bodies 20a and 20b. The trench 74 and the through-hole 30 are made by performing etching with conditions in which the etching rate of the silicon oxide film 79 belonging to the stacked body 20b of the upper level is lower than the etching rate of the non-doped polysilicon film 73 belonging to the stacked body 20a of the lower level. Thereby, the trench 74 and the through-hole 30 can be made to be straight. As a result, the distance between the trench 74 and the through-hole 30 can be designed to be short while reliably separating the trench 74 and the through-hole 30 from each other; and higher integration of the nonvolatile semiconductor memory device 1 can be realized.

In the embodiment, the lower portion of the through-hole 30 can be made efficiently because only the boron-doped polysilicon film 72 and the non-doped polysilicon film 73 exist inside the stacked body 20a and films that are difficult to etch such as silicon oxide films do not exist inside the stacked body 20a when making the through-hole 30 in the stacked body 20 in the processes illustrated in FIGS. 20A and 20B.

In the embodiment, the blocking insulating film 35 can fill the entire interior of the gap 76 because the deposited amount of the blocking insulating film 35 is not less than half of the distance between the gate electrodes 21 in the Z direction in the processes illustrated in FIGS. 22A and 22B. As a result, the subsequently-formed charge storage film 36 does not enter the gap 76. Accordingly, charge is not undesirably stored in a portion of the charge storage film 36 that enters the gap 76; and the characteristics of the memory cell transistor do not fluctuate due to the storage of such charge. Otherwise, the configuration, the manufacturing method, and the operational effects of the embodiment are similar to those of the first embodiment described above.

A fourth embodiment will now be described.

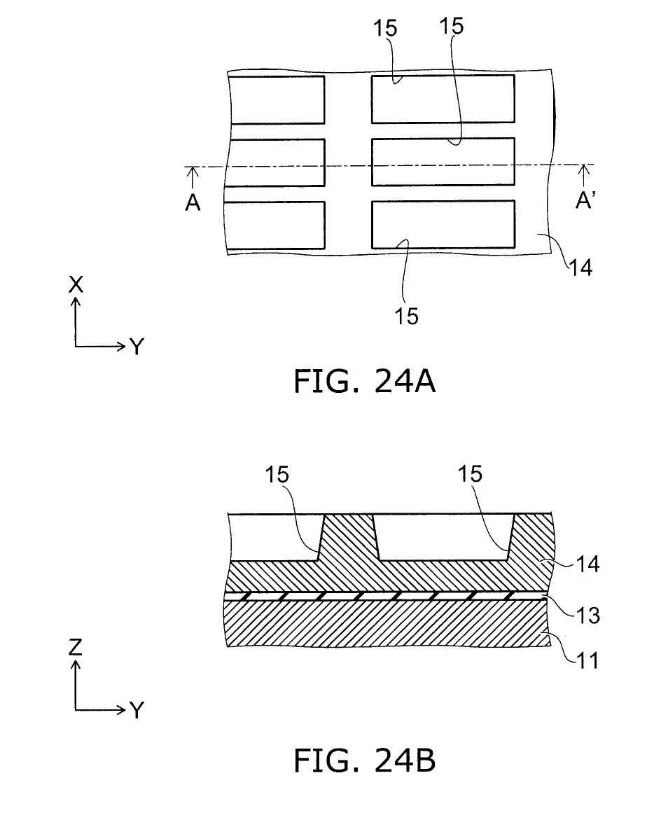

FIG. 24A to FIG. 37B illustrate a method for manufacturing a nonvolatile semiconductor memory device according to the embodiment. Drawing A of each of the drawings is a process plan view; and drawing B of each of the drawings is a process cross-sectional view along line A-A′ of drawing A.

FIG. 24A to FIG. 37B illustrate the memory array region Rm.

First, similarly to the third embodiment described above, the STI 12 is formed in the upper layer portion of the silicon substrate 11 as illustrated in FIGS. 11A to 11C; the transistor 61 is formed in the peripheral circuit region Rc; and the silicon oxide film 13 is formed on the upper surface of the silicon substrate 11 in the memory array region Rm.

Then, as illustrated in FIGS. 24A and 24B, the back gate electrode 14 is formed on the silicon oxide film 13 in the memory array region Rm; and the recess 15 is made in the upper surface thereof with a rectangular parallelepiped configuration having its longitudinal direction in the Y direction.

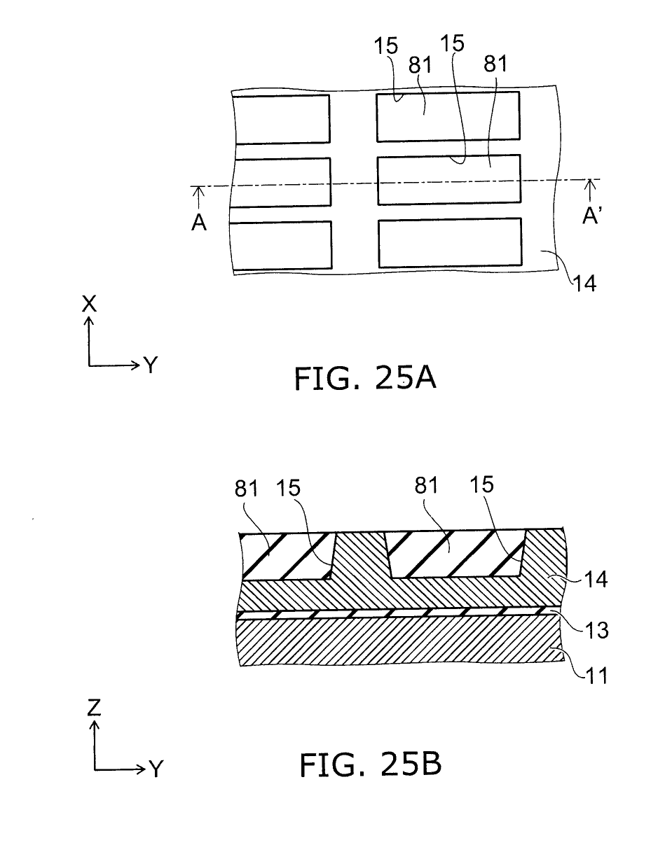

Continuing as illustrated in FIGS. 25A and 25B, silicon nitride is deposited on the entire surface; and the entire surface is etched. Thereby, the silicon nitride is removed from the upper surface of the back gate electrode 14 to expose the region of the upper surface of the back gate electrode 14 between the recesses 15; and a sacrificial member 81 made of silicon nitride is filled into the recess 15.

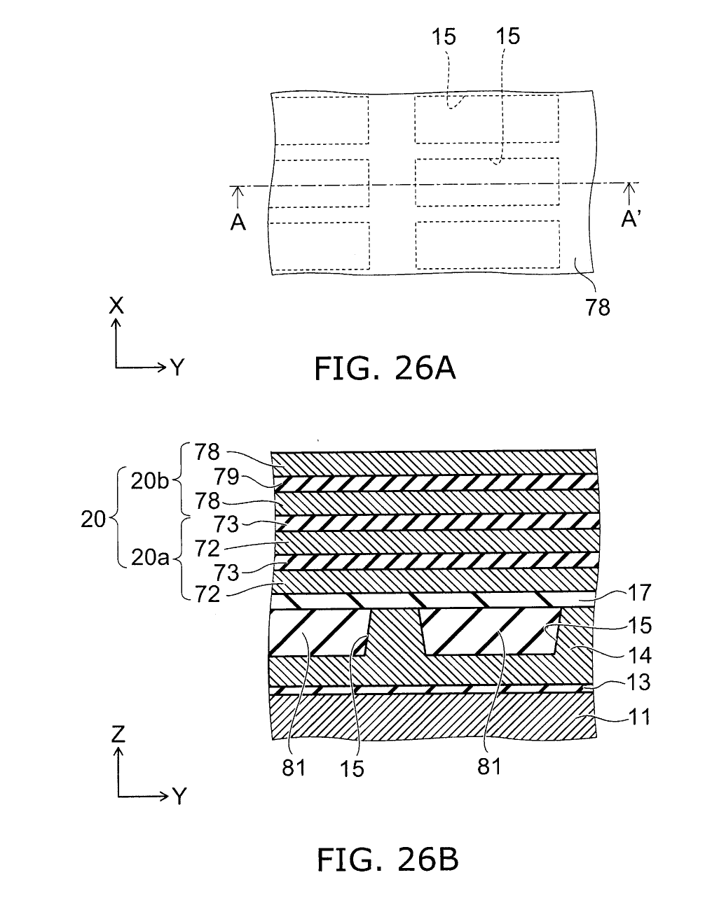

Then, as illustrated in FIGS. 26A and 26B, the silicon oxide film 17 is formed on the entire surface of the back gate electrode 14 and the sacrificial member 81. Continuing, the stacked body 20a is formed by alternately stacking the boron-doped polysilicon film 72 and the non-doped polysilicon film 73. Then, the stacked body 20b is formed by alternately stacking the boron-doped polysilicon film 78 and the silicon oxide film 79. Thereby, the stacked body 20a is formed on the silicon oxide film 17; and the stacked body 20b is formed thereon.

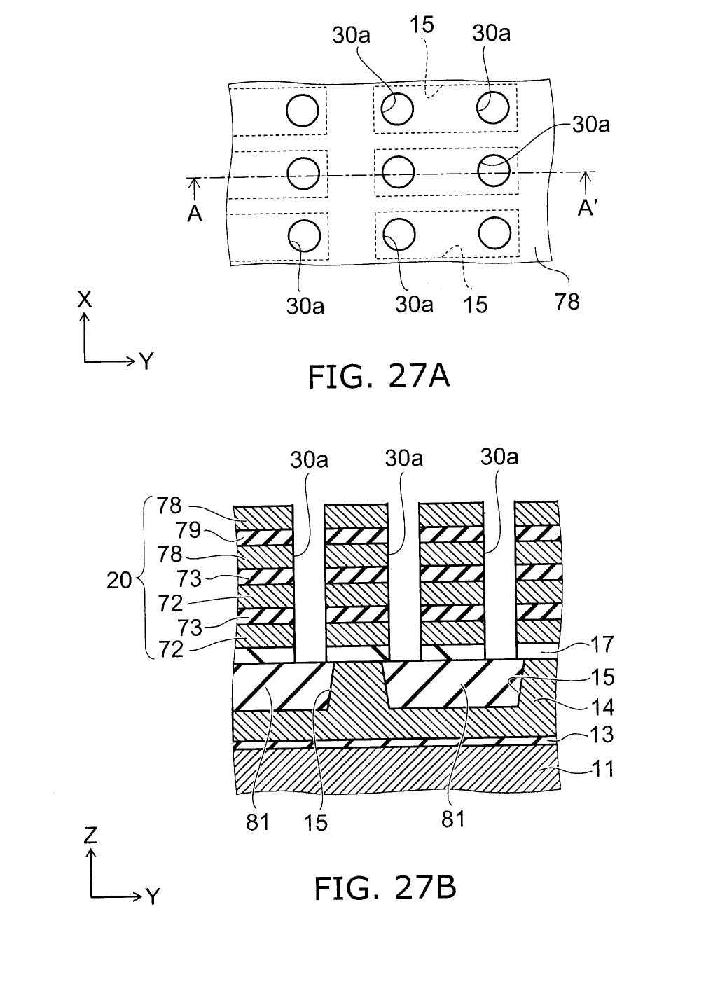

Continuing as illustrated in FIGS. 27A and 27B, a through-hole 30a is made in the stacked body 20 from the upper surface side thereof by performing photolithography and etching. The through-hole 30a is arranged in a matrix configuration along the X direction and the Y direction; and a pair of the through-holes 30a adjacent to each other in the Y direction reaches both of the Y-direction end portions of the recess 15. At this time, the etching is performed with conditions in which the etching rate of the silicon oxide film 79 is lower than the etching rate of the non-doped polysilicon film 73. For example, the etching is performed using a halogen-based gas and a fluorocarbon-based gas as the etching gas. Thereby, as described in regard to the first embodiment described above, the meandering of the through-hole 30a can be suppressed; and the through-hole 30a can be made to be straight.

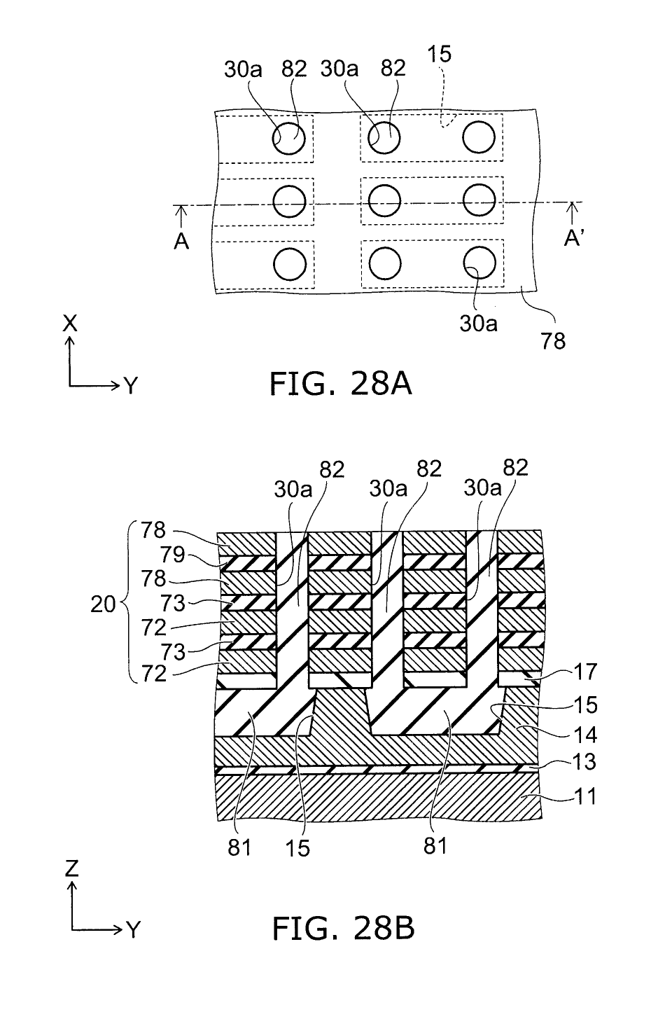

Continuing as illustrated in FIGS. 28A and 28B, silicon nitride is deposited on the entire surface; subsequently, the entire surface is etched; and the silicon nitride deposited on the upper surface of the stacked body 20 is removed. Thereby, a sacrificial member 82 made of silicon nitride is filled into the through-hole 30a.

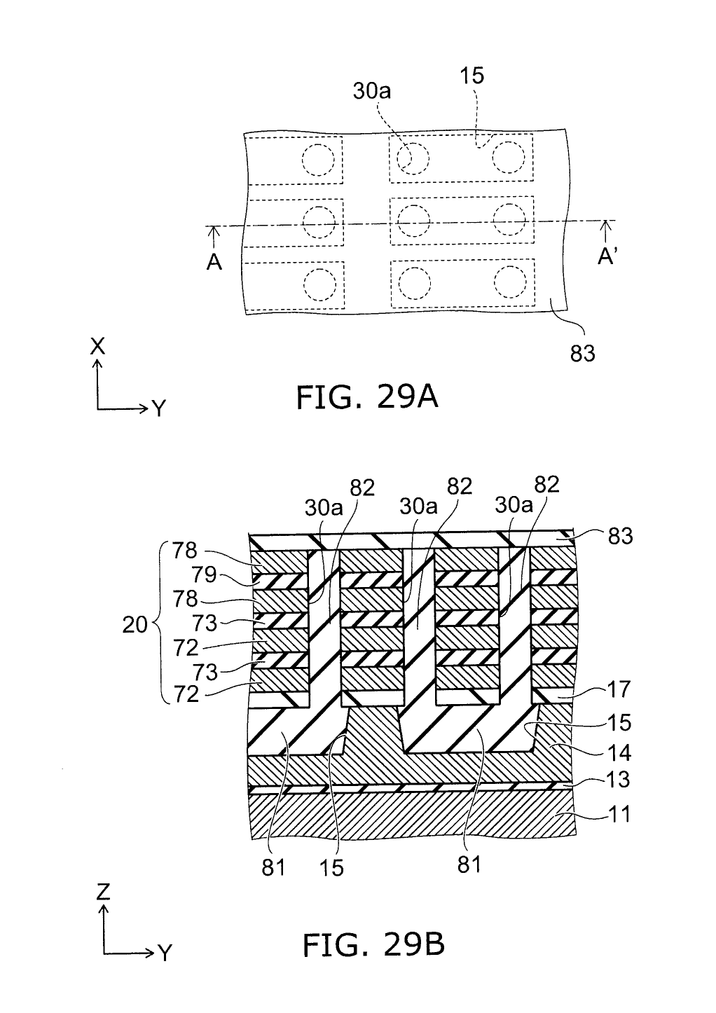

Then, as illustrated in FIGS. 29A and 29B, a silicon oxide film 83 is formed on the stacked body 20 to protect the boron-doped polysilicon film 78 of the uppermost layer.

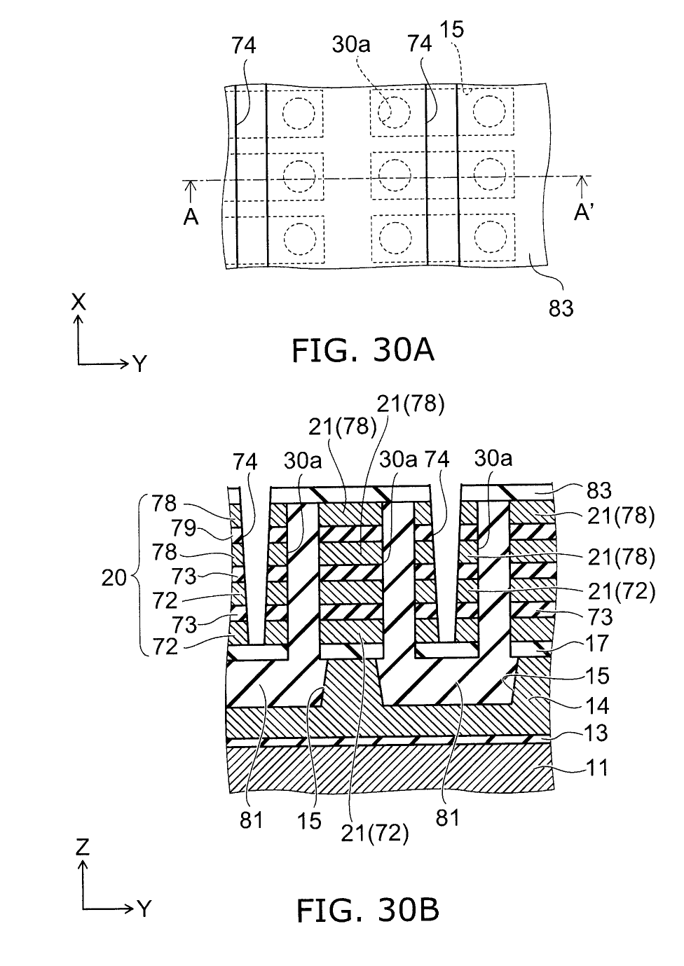

Continuing as illustrated in FIGS. 30A and 30B, the multiple trenches 74 are made in the stacked body 20 and the silicon oxide film 83 from the upper surface side by performing etching with conditions in which the etching rate of the silicon oxide film 79 is lower than the etching rate of the non-doped polysilicon film 73. Each of the trenches 74 is made extending in the X direction to pierce the silicon oxide film 83 and the stacked body 20 in the Z direction and pass through the region directly above the Y-direction central portion of the recess 15. Thereby, the boron-doped silicon layers 72 and 78 are divided into the multiple gate electrodes 21.

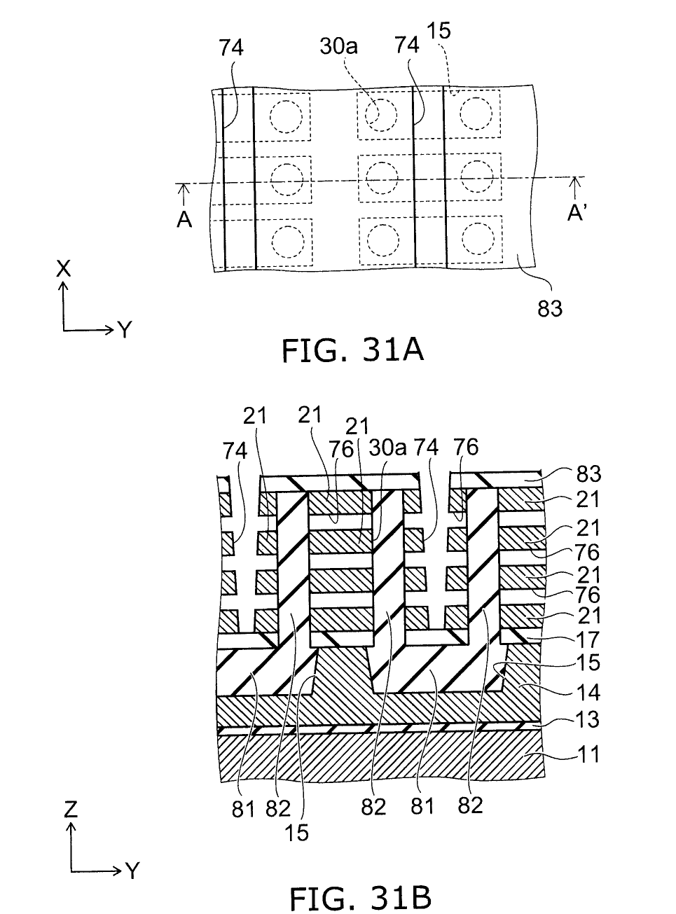

Then, as illustrated in FIGS. 31A and 31B, wet etching is performed via the trench 74 using, for example, an alkaline etchant. Thereby, the non-doped polysilicon film 73 inside the stacked body 20a (referring to FIG. 30B) is removed. Then, the wet etching is performed via the trench 74 using an etchant including, for example, hydrofluoric acid. Thereby, the silicon oxide film 79 inside the stacked body 20b (referring to FIG. 30B) is removed. As a result, the gap 76 forms between the gate electrodes 21 in the Z direction. At this time, the gate electrodes 21 are supported by the sacrificial member 82 which has a circular columnar configuration. Thus, in the embodiment, the non-doped polysilicon film 73 and the silicon oxide film 79 are removed by performing wet etching via the trench 74.

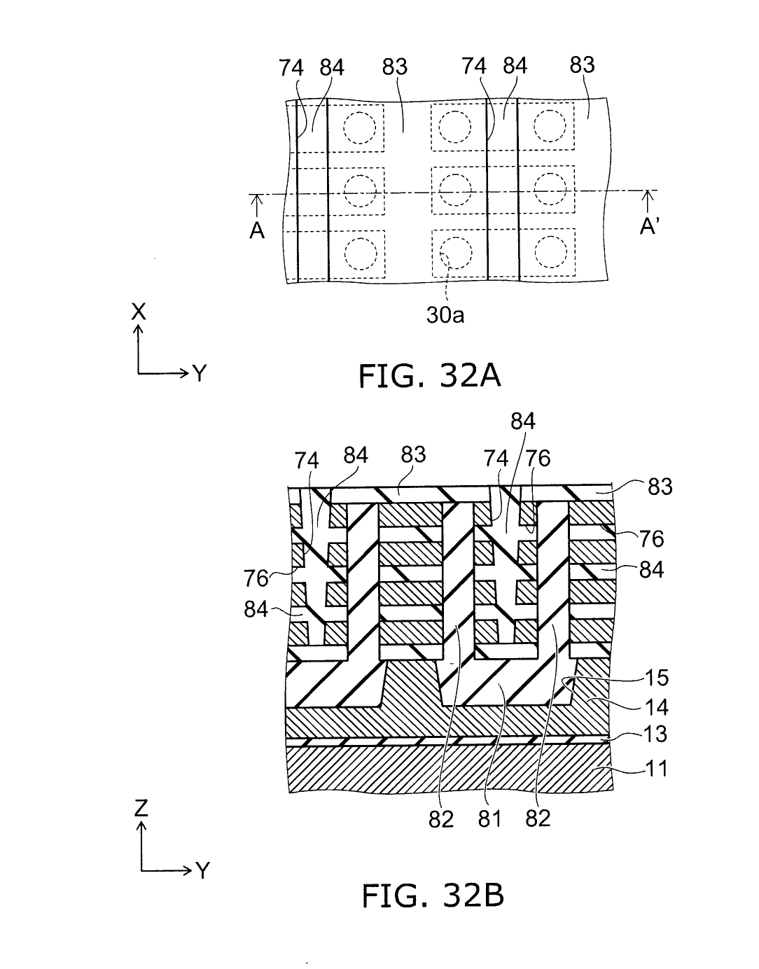

Continuing as illustrated in FIGS. 32A and 32B, silicon oxide is deposited on the entire surface using, for example, ALD. Thereby, a silicon oxide 84 is filled into the gap 76 and into the trench 74. As a result, an insulating film made of the silicon oxide 84 is formed inside the gap 76.

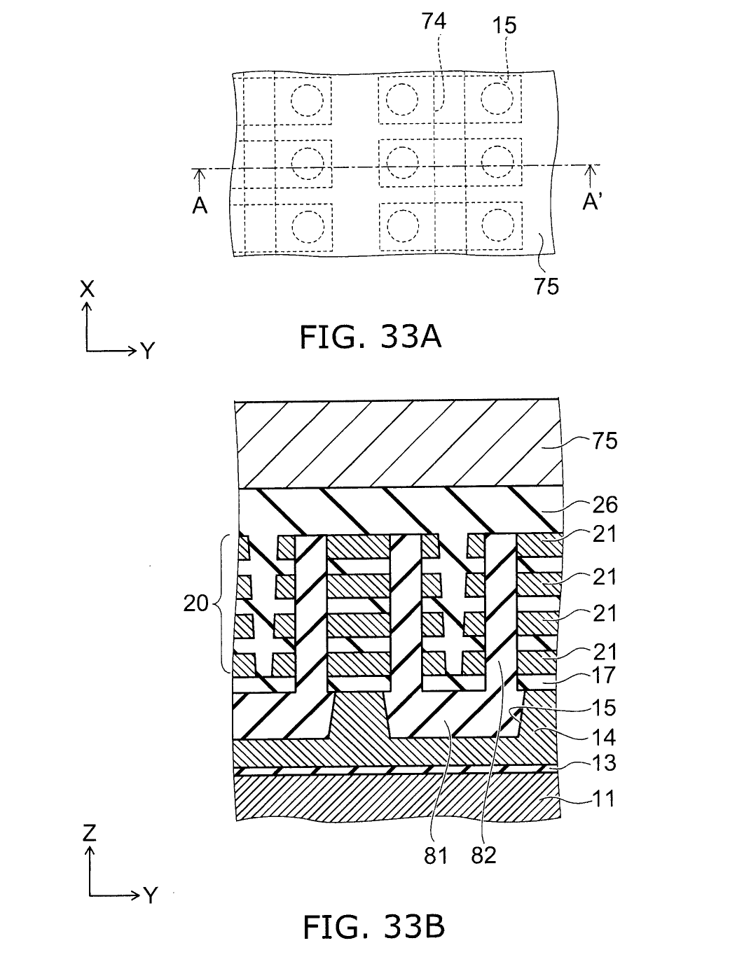

Then, as illustrated in FIGS. 33A and 33B, the silicon oxide film 26 is formed on the stacked body 20; and the boron-doped polysilicon film 75 is formed thereon.

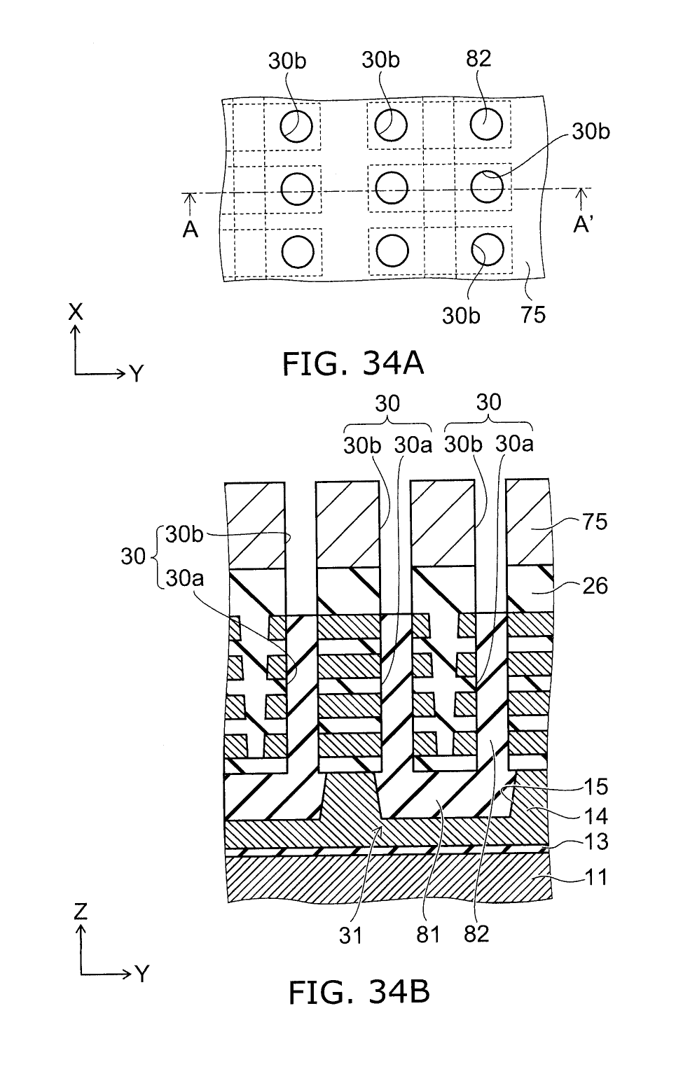

Continuing as illustrated in FIGS. 34A and 34B, a through-hole 30b is made in the boron-doped polysilicon film 75 and the silicon oxide film 26. The through-hole 30b is made in the region directly above the through-hole 30a to communicate with the through-hole 30a. A continuous through-hole 30 is made of the through-holes 30a and 30b. The U-shaped hole 31 is made of the through-holes 30 and the recess 15.

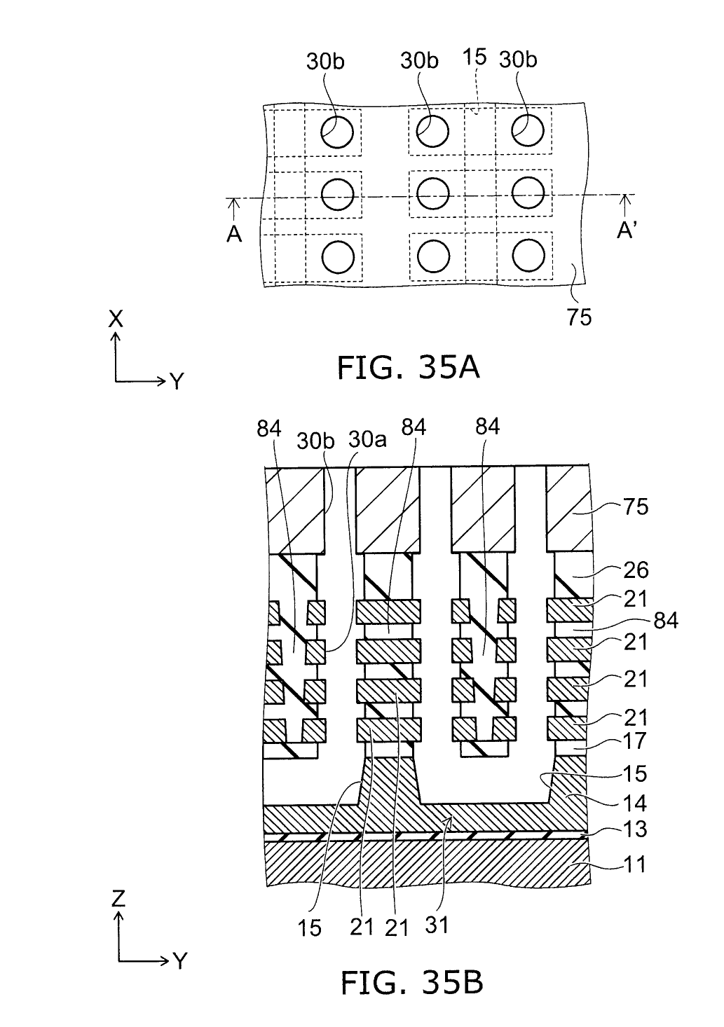

Then, as illustrated in FIGS. 35A and 35B, wet etching using hot phosphoric acid is performed to remove the sacrificial member 82 (referring to FIG. 34B) from the interior of the through-hole 30a and the sacrificial member 81 (referring to FIG. 34B) from the interior of the recess 15.

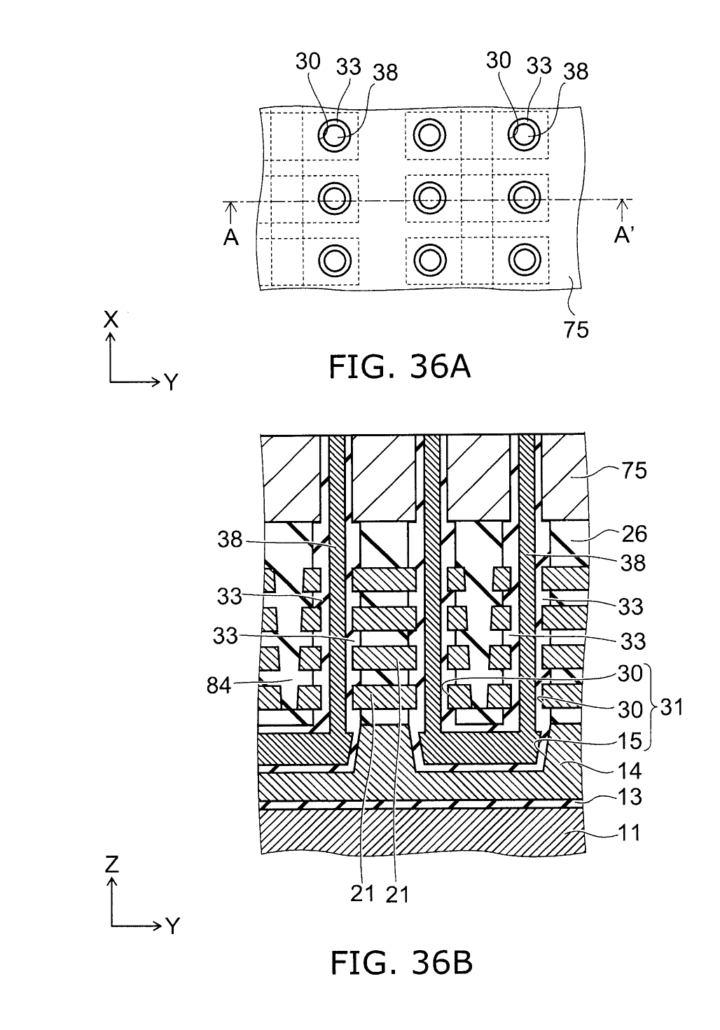

Continuing as illustrated in FIGS. 36A and 36B, the memory film 33 is formed by forming the blocking insulating film, the charge storage film, and the tunneling insulating film on the inner surface of the U-shaped hole 31. Subsequently, the U-shaped pillar 38 is formed by filling polysilicon into the U-shaped hole 31.

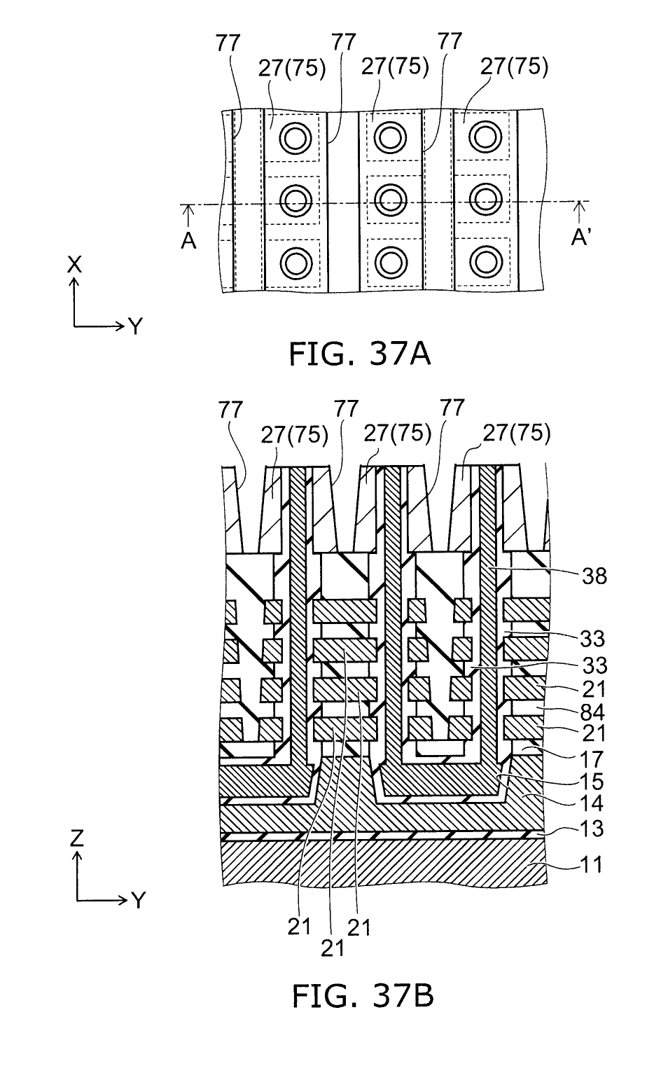

Then, as illustrated in FIGS. 37A and 37B, the slit 77 extending in the X direction is multiply made in the boron-doped polysilicon film 75 from the upper surface side thereof by performing photolithography and etching. Thereby, the boron-doped polysilicon film 75 becomes the multiple control electrodes 27 extending in the X direction.

The subsequent methods for manufacturing are similar to those of the third embodiment described above. In other words, the end portion of the stacked body 20 is patterned into a stairstep configuration and buried in the inter-layer insulating film 42; and the source line 47, the bit line 51, etc., are formed. Thereby, the nonvolatile semiconductor memory device according to the embodiment is manufactured.

In the nonvolatile semiconductor memory device according to the embodiment, the blocking insulating film 35 does not completely cover the upper surface and the lower surface of the gate electrode 21; the silicon oxide 84 is interposed between the gate electrodes 21; and the breakdown voltage between the gate electrodes 21 is guaranteed. Otherwise, the configuration, the manufacturing method, and the operational effects of the embodiment are similar to those of the third embodiment described above.

In the third and fourth embodiments described above, the gap 76 is made by removing the non-doped polysilicon film 73 and the silicon oxide film 79 via the through-hole 30 or the trench 74; and an insulating film is formed to separate the gate electrodes 21 from each other by filling an insulating material, i.e., the blocking insulating film 35 or the silicon oxide 84, into the gap 76. On the other hand, the boron-doped polysilicon films 72 and 78 remain and are used as the gate electrodes 21. However, the gate electrodes 21 may be formed by making a gap by removing the boron-doped polysilicon films 72 and 78 via the through-hole 30 or the trench 74 and by forming a conductive film in the gap by filling a conductive material, e.g., a metal material. Thereby, a metal gate having a low resistance can be realized. In such a case, the non-doped polysilicon film 73 and the silicon oxide film 79 may remain to be used as the insulating films that separate the gate electrodes 21 from each other.

According to the embodiments described above, a semiconductor memory device, a method for manufacturing a semiconductor memory device, and a method for manufacturing an integrated circuit device can be realized with higher integration.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A method for manufacturing a semiconductor memory device, comprising:
forming a first stacked body on a substrate by alternately stacking a first film and a second film;
forming a second stacked body on the first stacked body by alternately stacking a third film and a fourth film;
making a through-hole to pierce the second stacked body and the first stacked body by performing etching, an etching rate of the third film being lower than an etching rate of the first film in the etching;
forming a charge storage film on an inner surface of the through-hole; and
forming a semiconductor member in the through-hole,
the first film and the second film being formed of mutually different materials,
the third film and the fourth film being formed of mutually different materials,
the first film and the third film being formed of mutually different materials.

2. The method according to claim 1, wherein films belonging to one group selected from a group consisting of the first film and the third film and a group consisting of the second film and the fourth film are conductive, and films belonging to the other group are insulative.

3. The method according to claim 1, wherein the second film and the fourth film are formed of the same material.

4. The method according to claim 3, wherein:
the first film is formed of silicon without an introduced impurity;
the third film is formed of silicon oxide; and
the second film and the fourth film are formed of silicon having boron introduced.

5. The method according to claim 3, wherein:
the first film is formed of silicon nitride;
the third film is formed of silicon without an introduced impurity; and
the second film and the fourth film are formed of silicon oxide.

6. The method according to claim 1, further comprising making a trench in the first stacked body and the second stacked body to pierce the first stacked body and the second stacked body.

7. The method according to claim 6, further comprising removing the first film and the third film via the trench, and
forming a fifth film inside a gap made by the removing of the first film and the third film.

8. The method according to claim 1, further comprising
removing the first film and the third film via the through-hole, and
forming a fifth film inside a gap made by the removing of the first film and the third film.

9. The method according to claim 7, wherein
the second film and the fourth film are conductive, and the fifth film is insulative.

10. The method according to claim 7, wherein
the second film and the fourth film are insulative, and the fifth film is conductive.

11. The method according to claim 1, wherein a proportion of a thickness of the second stacked body to a total thickness of the first stacked body and the second stacked body is 20% to 80%.

12. The method according to claim 11, wherein the proportion is not more than 60%.

13. A method for manufacturing an integrated circuit device, comprising:
forming a first stacked body by alternately stacking a first film and a second film;
forming a second stacked body on the first stacked body by alternately stacking a third film and a fourth film; and
making a trench or a hole to pierce the first stacked body and the second stacked body by performing etching with an etching rate of the third film being lower than an etching rate of the first film,
the first film and the second film being formed of mutually different materials,
the third film and the fourth film being formed of mutually different materials,
the first film and the third film being formed of mutually different materials.

14. A semiconductor memory device, comprising:
a substrate;
a first stacked body provided on the substrate including first films and second films stacked alternately;
a second stacked body provided on the first stacked body including third films and fourth films stacked alternately;
a charge storage film provided on an inner surface of a through-hole piercing the first stacked body and the second stacked body; and
a semiconductor member provided in the through-hole,
the first film and the second film being formed of mutually different materials,
the third film and the fourth film being formed of mutually different materials,
the first film and the third film being formed of mutually different materials,
films belonging to one group selected from a group consisting of the first film and the third film and a group consisting of the second film and the fourth film being conductive, films belonging to the other group being insulative.

15. The device according to claim 14, wherein a trench is made in the first stacked body and the second stacked body to pierce the first stacked body and the second stacked body.

16. The device according to claim 14, wherein the second film and the fourth film are formed of the same material.

17. The device according to claim 16, wherein:
the first film is formed of silicon without an introduced impurity;
the third film is formed of silicon oxide; and
the second film and the fourth film are formed of silicon having boron introduced.

18. The device according to claim 16, wherein:
the first film is formed of silicon nitride;
the third film is formed of silicon without an introduced impurity; and
the second film and the fourth film are formed of silicon oxide.

19. The device according to claim 14, wherein a proportion of a thickness of the second stacked body to a total thickness of the first stacked body and the second stacked body is 20% to 80%.

20. The device according to claim 19, wherein the proportion is not more than 60%.
